(19) United States
(12) Patent Application Publication
(10) Pub. No.: US 2011/0193558 A1
(43) Pub. Date: Aug. 11, 2011

(54) PASSENGER SCANNING SYSTEMS FOR DETECTING CONTRABAND

(75) Inventors: Christopher W. Crowley, San Diego, CA (US); Erik Edmund Magnuson, Cardiff, CA (US); Alejandro Bussandri, La Jolla, CA (US); Yotam Margalit, Castro Valley, CA (US); Hector Robert, San Diego, CA (US)

(73) Assignee: MORPHO DETECTION, INC., Newark, CA (US)

(21) Appl. No.: 13/019,927

(22) Filed: Feb. 2, 2011

Related U.S. Application Data
(60) Provisional application No. 61/300,778, filed on Feb. 2, 2010.
(60) Provisional application No. 61/300,779, filed on Feb. 2, 2010.
(60) Provisional application No. 61/301,343, filed on Feb. 4, 2010.
(60) Provisional application No. 61/303,232, filed on Feb. 10, 2010.
(60) Provisional application No. 61/304,724, filed on Feb. 15, 2010.
(60) Provisional application No. 61/322,081, filed on Apr. 8, 2010.

(51) Int. Cl. G01R 19/00

(52) U.S. Cl. 324/300

(57) ABSTRACT

A passenger scanning system includes a passenger screening area configured for a person to enter and a shield surrounding at least a portion of the passenger screening area. The shield is configured to reduce a radio frequency interference within the passenger screening area. The passenger scanning system also includes one or more sensors positioned in the passenger screening area at a height configured to be proximate one or more of an abdominal region, a groin region, and a pelvic region of the entered person. The sensors are configured to generate a signal in response to a target substance located in the one or more of the abdominal region, the groin region, and the pelvic region.

### CROSS REFERENCE TO RELATED APPLICATIONS

This application claims the benefit of U.S. Patent Application Nos. 61/300,778, and 61/300,779, filed Feb. 2, 2010, U.S. Patent Application No. 61/301,343, filed Feb. 4, 2010, U.S. Patent Application No. 61/303,232, filed Feb. 10, 2010, U.S. Patent Application No. 61/304,724, filed Feb. 15, 2010, and U.S. Patent Application No. 61/322,081, filed Apr. 8, 2010, which are all hereby incorporated by reference in their entireties.

### BACKGROUND OF THE INVENTION

The embodiments described herein relate generally to inspection systems used to inspect a person and, more particularly, to an inspection system configured to inspect a person for a target material.

The Transportation Security Administration (TSA) has recently mandated more stringent inspection procedures be implemented by the travel industry to reduce the possibility of passengers boarding a carrier, such as an aircraft, carrying contraband, such as concealed weapons, explosives, and/or other contraband. To facilitate preventing passengers boarding a plane carrying contraband, such as concealed weapons, explosives, and/or other contraband, the TSA requires that all passengers be screened and/or inspected prior to boarding the carrier.

In some known inspection systems, passengers arriving at the airport terminal are examined by trace detection systems. Trace detection systems may detect and analyze particles and/or substances derived from a person to determine if the person has been in proximity to contraband items. However, such systems may not detect a contraband item concealed beneath multiple layers of clothing or inside a body cavity.

In some known inspection systems, passengers arriving at the airport terminal are subjected to whole body imaging. Whole body imaging systems, such as millimeter-wave (MMW) and X-ray backscatter (XRB) systems, provide a picture of articles that might be hidden under clothing. However, the whole body imaging systems may not be able to detect all articles.

Some known inspection systems employ nuclear quadrupolar resonance (NQR) sensors in the floor of a walkthrough or walk-in device. As the passenger stands in the central portion of the device, the NQR sensors operate to detect contraband objects in or on the passenger's shoes, socks, or articles of clothing. However, such devices are most effective at detecting contraband located at lower extremities of the passenger. For example, at least some known inspection systems utilizing inductive sensors have employed various techniques for shielding the system from external noise. One technique is to completely enclose the sensor in an electrically connected and grounded box. Another technique which is commonly used for NQR sensors, is to position the sensor within an enclosure having a wave-guide tunnel positioned at the entrance and exit to the inspection system. While such configurations have enjoyed considerable success in many respects, their use has been limited for inspecting humans since some people are wary or uncomfortable about having to walk and stand in confined spaces.

### BRIEF SUMMARY OF THE INVENTION

In one aspect, a passenger scanning system includes a passenger screening area configured for a person to enter, and a shield surrounding at least a portion of the passenger screening area, wherein the shield is configured to reduce a radio frequency interference within the passenger screening area. The system also includes one or more sensors each positioned in the passenger screening area at a height configured to be proximate one or more of an abdominal, groin and pelvic region of the entered person, wherein the one or more sensors is configured to generate a signal in response to a target substance located in the one or more of the abdominal, groin and pelvic region.

In another aspect, a passenger scanning system includes at least one wall and a platform coupled to the wall to define a chair configured to support a person. The system also includes a detection system comprising at least one inductive sensor configured to detect a change in a magnetic field of the person indicative of a presence of a target substance.

In another aspect, a passenger scanning system includes a first sidewall, and a second sidewall positioned opposite the first sidewall, such that a passage is defined along a medial plane of the passenger scanning system and between the first and second sidewalls. The system also includes a first current branch positioned within the passage and on a first side of the medial plane, and a second current branch positioned within the passage and on a second side of the medial plane opposing the first side, wherein the first current branch and the second current branch have anti-symmetric current flow. The system also includes a safety device configured to limit undesirable heat generation within the passenger scanning system.

### BRIEF DESCRIPTION OF THE DRAWINGS

FIG. 1 shows an abdomen scanner system that includes a passenger screening area.

FIG. 2 is a perspective view of an abdomen scanner system incorporated as part of a passenger screening system.

FIG. 3 is a top view of an abdomen scanner system incorporated as part of a passenger screening system.

FIG. 4 is a top view of an abdomen scanner system incorporated as part of a passenger screening system.

FIG. 5 is a perspective view of an alternative abdomen scanner system.

FIG. 6 is a top view of the abdomen scanner system shown in FIG. 5.

FIG. 7 is a schematic block diagram of an exemplary electrical architecture that may be used with the abdomen scanner system shown in FIGS. 5 and 6.

FIG. 8 is a schematic illustration of an exemplary inductive sensor that may be used with the abdomen scanner system shown in FIGS. 5 and 6.

FIGS. 9, 10, and 11 are perspective, side, and end-views, respectively, of a lower extremity scanner system.

FIG. 12 is an end-view of the scanner system shown in FIGS. 9-11, with the inductive sensor omitted to show the sensor housing.

FIGS. 13A and 13B are schematic views depicting primary electrical components of an inductive sensor that may be used with the scanner system shown in FIGS. 9-12.

FIG. 14 is a partial cross-sectional view of the system shown in FIGS. 9-11, with the inductive sensor positioned within the sensor housing.

FIGS. 15A and 15B are schematic views depicting primary electrical components of an alternative inductive sensor that may be used with the scanner system shown in FIGS. 9-12.

FIG. 16 is a partial cross-sectional view of the scanner system shown in FIGS. 9-11 including the inductive sensor shown in FIGS. 15A and 15B.

FIGS. 17A and 17B are schematic views depicting primary electrical components of another alternative inductive sensor.

FIG. 18 is a partial cross-sectional view of the scanner system shown in FIGS. 9-11 including the inductive sensor shown in FIGS. 17A and 17B.

FIG. 19 is an end-view of the scanner system shown in FIGS. 9-11, including an optional metal detector.

FIG. 20 is a perspective view of an alternative lower extremity scanner system that is adapted for use in a multi-sensor inspection system.

FIGS. 21 and 22 are perspective and end-views, respectively, of a multi-sensor inspection system.

FIG. 23 is a cross-sectional view of the multi-sensor inspection system shown in FIGS. 21 and 22 taken along line 15-15 in FIG. 22.

FIGS. 24, 25, and 26 are perspective, side, and end-views, respectively, of an alternative lower extremity scanner system.

FIG. 27 is a top-view of a portion of the scanner system shown in FIGS. 24-26, showing a relative positioning of a left current branch and a right current branch.

FIG. 28 is a side-view of the inductive sensor shown in FIGS. 24-26.

FIG. 29 is a partial cross-sectional view of the scanner system shown in FIGS. 24-26.

FIG. 30 is block diagram of a system which may be implemented to control, manage, operate, and monitor the various inspection and detection systems shown in FIGS. 9-29.

FIGS. 31, 32, and 33 are perspective, top, and end-views, respectively, of a walkthrough detection portal including a quadrupole (QR) inspection system.

FIG. 34 is a cross-sectional view of the walkthrough detection portal shown in FIGS. 31-33 taken along line 34-34 in FIG. 33.

FIG. 35 is an exploded perspective view of another embodiment of a shoe scanner system incorporated as part of a passenger scanning system.

FIG. 36 is a perspective view of another embodiment of a shoe scanner system incorporated as part of a passenger scanning system.

FIG. 37 is a perspective view of a wanding station that may be used to scan a person for a target substance.

FIG. 38 is an enlarged partial view of the wanding station shown in FIG. 37 taken at area 38.

FIG. 39 is a top plan view of the wanding station shown in FIG. 37.

FIG. 40 is a side view of the wanding station shown in FIG. 39 taken at line 40-40.

FIG. 41 is a top plan view of an alternative wanding station.

FIG. 42 is a side view of the wanding station shown in FIG. 41 taken at line 42-42.

FIG. 43 is a perspective view of a wand that may be used with the wanding station shown in FIGS. 41 and 42.

FIG. 44 is a perspective view of a gantry that may be used with the wanding station shown in FIGS. 37-39 and/or the wanding station shown in FIGS. 41 and 42.

FIG. 45 is a schematic view of a trace detection system that may be used with the wanding station shown in FIGS. 37-39 and/or the wanding station shown in FIGS. 41 and 42.

### DETAILED DESCRIPTION OF THE INVENTION

Described herein are scanner systems that include inductive sensors positioned to find contraband located in or near a passenger's body. For example, embodiments of the scanner system can detect contraband concealed in a passenger's abdominal, pelvic and/or groin area, such as between the passenger's legs or inside a body cavity. As used herein, the term “contraband” refers to illegal substances, explosives, narcotics, weapons, a threat object, and/or any other material that a person is not allowed to possess in a restricted area, such as an airport. Alternatively, embodiments of the scanner system can detect contraband positioned near the passenger's feet or in the passenger's shoes.

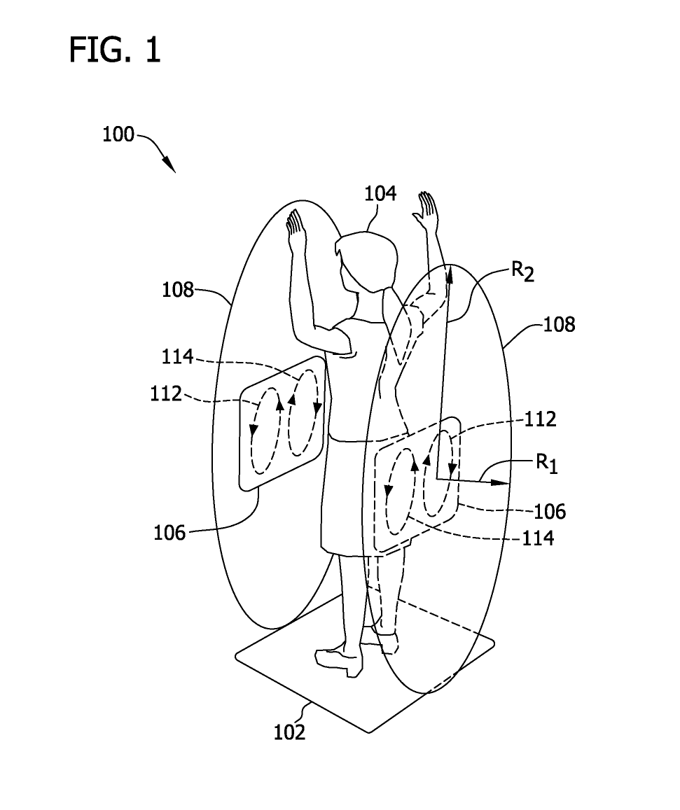

FIGS. 1-4 illustrate a first embodiment of an abdomen scanner system for use in detecting contraband positioned within or near a passenger.

FIG. 1 illustrates an abdomen scanner system 100 that includes a passenger screening area 102. A passenger 104 to be scanned is located within passenger screening area 102. One or more sensors 106 are positioned at a height expected to approximate the height of the abdomen of an average passenger. Each sensor 106 may be implemented using any type of inductive sensor, including an NQR sensor, a nuclear magnetic resonance (NMR) sensor, a metal detection sensor, and the like. For convenience only, various embodiments will be described with reference to the sensor 106 implemented as an NQR sensor, but such description is equally applicable to other types of inductive sensors.

In some embodiments, a height of the one or more sensors 106 is adjustable to match the abdominal height of each passenger 104. In certain embodiments, the abdominal height is defined as a distance that extends approximately between the passenger's knee and chest. Because passenger screening often takes place in an environment with significant radio frequency interference, in some embodiments shielding 108 is located around passenger screening area 102 to increase a signal-to-noise ratio. Shielding 108 may include conductive plates connecting a floor (not shown) and a ceiling (not shown) in passenger screening area 102. In some embodiments, a characteristic length R₁ of shielding 108 is less than a characteristic length R₂ of shielding 108.

In the exemplary embodiment, sensors 106 are operated at or near a normal human body temperature, i.e., approximately 37.0° C. In some embodiments, however, sensors 106 are operated within a range of the normal human body temperature, such as plus or minus approximately six degrees Celsius. Accordingly, in the exemplary embodiment, sensors 106 are operated at an operating frequency that is associated with the normal human body temperature. In some embodiments, however, sensors 106 are operated within a range of operating frequencies that is associated with a range of temperatures that includes the normal human body temperature. For example, in some embodiments, the operating frequency of sensors 106 is shifted by approximately 100 Hz per degree Celsius. Moreover, in some embodiments, the operating frequency of sensors 106 is shifted inversely with respect to temperature. For example, the operating frequency of sensors 106 decreases as the temperature increases. In one embodiment, the operating frequency of sensors 106 is controlled by an operator at control system 110. Moreover, in some embodiments, sensors 106 are capable of operating at multiple frequencies. For example, sensors 106 may be operated initially in a safe mode, using a lower power, to detect a medical device, and may then be operated in a detection mode, using a higher power, to detect contraband.

During the scanning process, each sensor 106 may provide radio frequency excitation signals and pick up resulting signals that indicate the presence of contraband. For example, each sensor 106 may be an NQR sensor that provides radio frequency excitation signals at a frequency generally corresponding to a predetermined, characteristic NQR frequency of the target contraband substance. Each sensor 106 that is an NQR sensor also may act as a pick-up coil to detect any resulting NQR signals emanating from contraband concealed by passenger 104. These signals may be communicated to any suitable computing device for processing and analysis. Abdomen scanner system 100 thus may use safe, non-ionizing radiation to target specific chemical components of contraband.

Each sensor 106 may be implemented using two antisymmetric current branches 112 and 114. The term “anti-symmetric” refers to the condition in which current flows through current branch 112 of sensor 106 in a direction substantially opposite the direction of current flow through current branch 114, as indicated by the arrows in FIG. 1. The anti-symmetric current flow produces counter-directed magnetic fields that are well-attenuated and have a topography that is especially suited for examination of the proximately positioned abdominal area of passenger 104, including body cavities.

In some embodiments, the one or more sensors 106 include two sensors 106 located opposite each other in passenger screening area 102, as shown in FIG. 1. In other embodiments, the one or more sensors 106 include two sensors 106 located between zero and 180 degrees apart from each other (not shown) in passenger screening area 102. These arrangements of two sensors 106 have the effect of reducing a susceptibility of abdomen scanner system 100 to radio frequency interference and targeting a sensitivity of abdomen scanner system 100 to the abdominal region of interest. Additionally or alternatively, in some embodiments, one or more sensors 106 have current branch 112 and current branch 114 located closer together than in traditional inductive sensors to create a smaller, more locally focused coil system that has a higher signal to noise ratio than traditional inductive sensors.

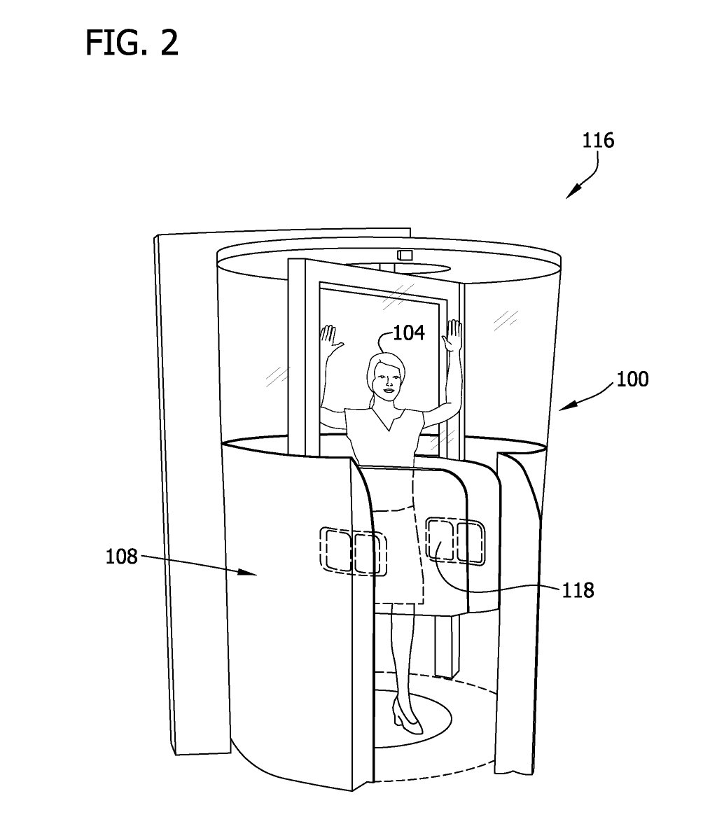

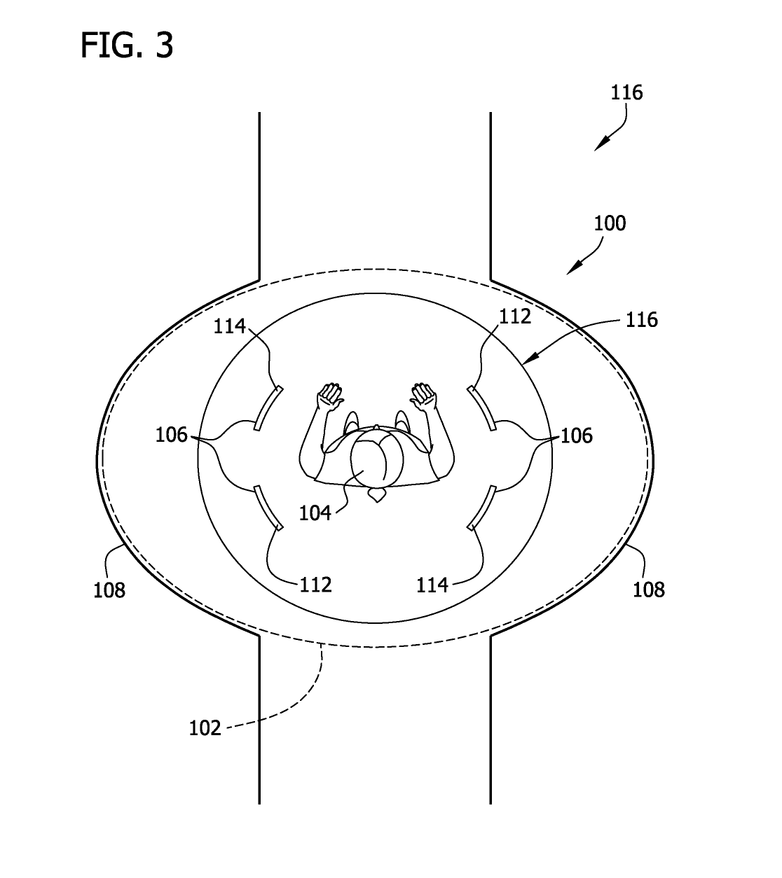

FIGS. 2 and 3 illustrate alternative embodiments of the abdomen scanner system shown in FIG. 1, wherein abdomen scanner system 100 is incorporated as part of a passenger screening system 116. FIG. 2 is a perspective view and FIG. 3 is a top view of abdomen scanner system 100 incorporated as part of a passenger screening system 116, including a MMW whole body imaging system 118. While passenger screening system 116 is shown as including a MMW whole body imaging system 118, it may also or alternatively include one or more of an XRB whole body imaging system, a trace detection system, a metal detector system, a wand detector system, or other passenger screening device. In addition, abdomen scanner system 100 is shown as being physically integrated into MMW whole body imaging system 118, but in alternative embodiments abdomen scanner system 100 may be at a separate location from some or all other systems within passenger screening system 116.

Passenger 104 stands within passenger screening area 102. Passenger screening area 102 is surrounded by shielding 108. As shown in FIG. 2, shielding 108 may be at least partially composed of semi-transparent material to reduce a perception by passenger 104 of confinement. In some embodiments, shielding 108 includes an aluminum honeycomb structure.

MMW whole body imaging system 118 is located between shielding 108 and passenger 104. MMW whole body imaging system 118 is configured to provide a picture of articles that might be hidden under clothing of passenger 104. Inside MMW whole body imaging system 118 are one or more sensors 106 each including a current branch 112 and current branch 114. Sensors 106 are located proximate passenger 104 in order to increase a sensitivity of abdomen scanner system 100 and limit an interference of MMW whole body imaging system 118 with sensors 106. In addition, although sensors 106 are located between MMW whole body imaging system 118 and passenger 104, in some embodiments sensors 106 produce only a small “shadow,” or obscured area, in a whole body image produced by MMW whole body imaging system 118, because of a compact size of sensors 106. Thus, abdomen scanner system 100 may be integrated with MMW whole body imaging system 118 to reduce a footprint of passenger screening area 102.

Moreover, in some embodiments, abdomen scanner system 100 operates simultaneously with MMW whole body imaging system 118. Thus, abdomen scanner system 100 may be integrated with MMW whole body imaging system 118 to reduce a time required to screen passenger 104 for contraband. In alternative embodiments, abdomen scanner system 100 operates in sequence with MMW whole body imaging system 118.

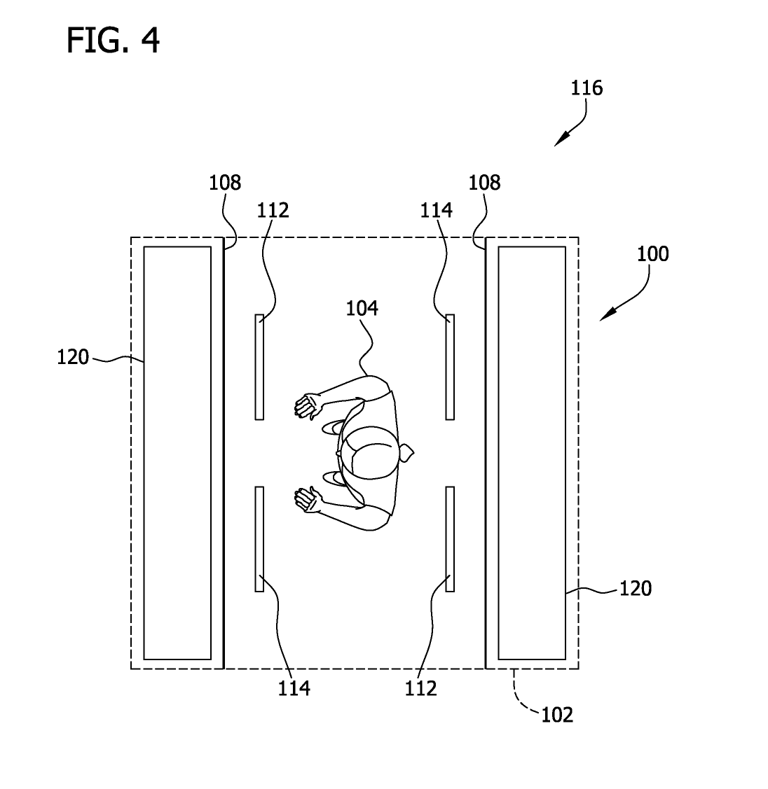

FIG. 4 is another alternative embodiment of the abdomen scanner system shown in FIG. 1. Specifically, FIG. 4 is a top view of abdomen scanner system 100 incorporated as part of a passenger screening system 116, including an XRB whole body imaging system 120. Passenger 104 stands within passenger screening area 102. Sensors 106 are located proximate passenger 104 in order to increase a sensitivity of abdomen scanner system 100 and limit an interference of XRB whole body imaging system 120 with sensors 106. In addition, although sensors 106 are located between XRB whole body imaging system 120 and passenger 104, in some embodiments sensors 106 produce only a small “shadow,” or obscured area, in a whole body image produced by XRB whole body imaging system 120, because of a compact size of sensors 106. Additionally, as shown in FIG. 4, in some embodiments shielding 108 is sufficiently thin to be located between passenger 104 and XRB whole body imaging system 120 without degrading a quality of an image produced by XRB whole body imaging system 120. For example, in some embodiments shielding 108 is equivalent to a thick sheet of aluminum foil. Thus, abdomen scanner system 100 may be integrated with XRB whole body imaging system 120 to reduce a footprint of passenger screening area 102.

Moreover, in some embodiments, abdomen scanner system 100 operates simultaneously with XRB whole body imaging system 120. Thus, abdomen scanner system 100 may be integrated with XRB whole body imaging system 120 to reduce a time required to screen passenger 104 for contraband. In alternative embodiments, abdomen scanner system 100 operates in sequence with XRB whole body imaging system 120.

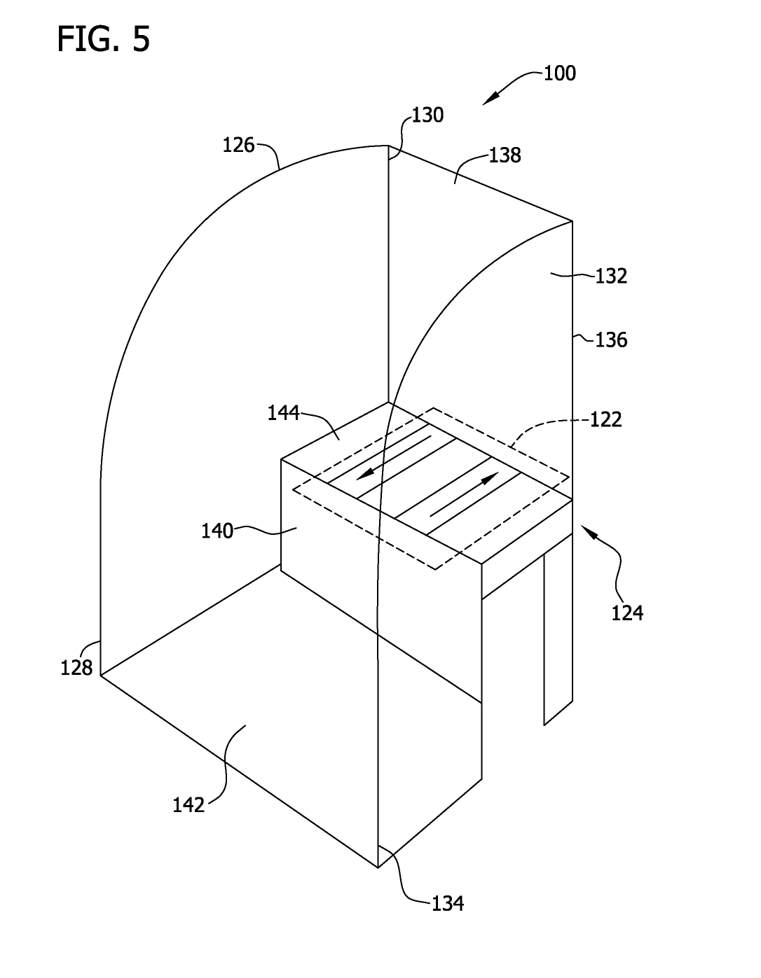

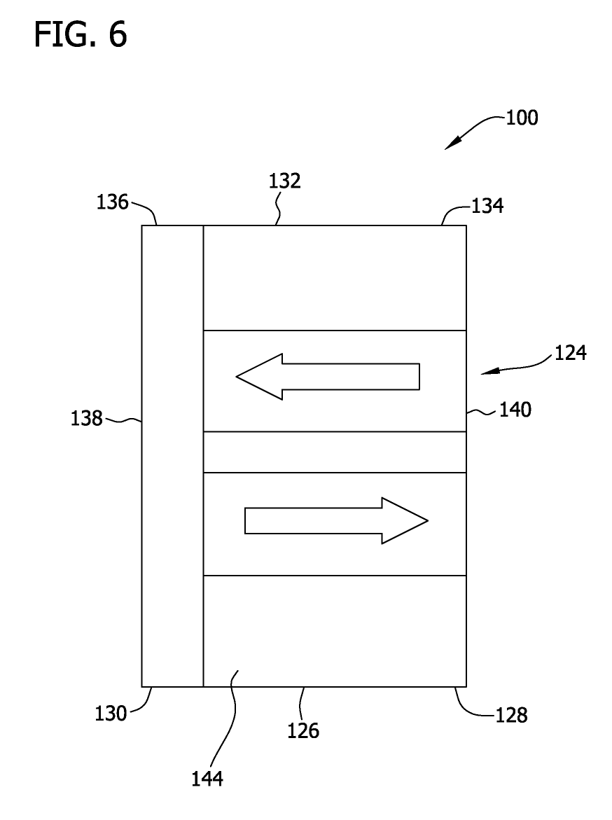

FIG. 5 is a perspective view of another alternative embodiment of an abdomen system 100, and FIG. 6 is a top view of the alternative abdomen scanner system 100. In the exemplary embodiment, system 100 includes at least one modality 122 for use as an explosive and/or narcotics detection system. In some embodiments, system 100 also includes a second modality (not shown) for use as a metal detection system. Examples of the second modality include, but are not limited to only including, millimeter wave imaging technologies, backscatter imaging technologies, or trace detection technologies. In the exemplary embodiment, system 100 also includes at least one computer (not shown in FIGS. 5 and 6), and a communications bus (not shown in FIGS. 5 and 6) that couples modality 122 and the computer. The bus enables operator commands and inputs to be input into the computer and to be communicated to modality 122. Moreover, the bus enables output, such as detection data, generated by modality 122 to be communicated to the computer for analysis. In some embodiments, the computer includes one or more computer-readable storage media having computer-executable components or instructions stored thereon for performing the operations described herein.

In the exemplary embodiment, modality 122 and the computer are provided in a single housing or chair 124. In an alternative embodiment, modality 122 and the computer are separately housed, for example, to prevent tampering. In such an embodiment, modality 122 is provided within chair 124. In the exemplary embodiment, system 100 includes a first wall 126 having a first end 128 and a second end 130, and a second wall 132 that is positioned substantially parallel to first wall 126 and includes a first end 134 and a second end 136. First wall 126 and second wall 132 are each formed with an arcuate shape that has a radius that approximates a height of each wall 126 and 132. Moreover, system 100 includes a third wall 138 that is positioned substantially perpendicular to first and second walls 126 and 132 and extends from second end 130 to second end 136. Further, system 100 includes a fourth wall 140 that is positioned substantially parallel to third wall 138. Fourth wall 140 extends between first and second walls 126 and 132, and is positioned between first ends 128 and 134 and second ends 130 and 136. System 100 also includes a floor 142 that extends between first and second walls 126 and 132. Floor 142 also extends from first ends 128 and 134 towards fourth wall 140.

In the exemplary embodiment, system 100 also includes a platform 144 that extends between first and second walls 126 and 132, and between third and fourth walls 138 and 140 such that platform 144 is positioned parallel to floor 142. Moreover, in the exemplary embodiment, platform 144 includes an inductive sensor device (not shown in FIGS. 5 and 6), which is described in greater detail below. First wall 126, second wall 132, and third wall 138 define an opening that enables a passenger to enter and exit chair 124 through the same opening. Moreover, first wall 126, second wall 132, third wall 138, and platform 144 define chair 124 to enable a passenger to sit during a scan. In an alternative embodiment, first wall 126, second wall 132, and third wall 138 are integrally formed to define chair 124 in conjunction with platform 144. For example, first wall 126, second wall 132, and third wall 138 may form a substantially arcuate shape, such as a parabolic shape.

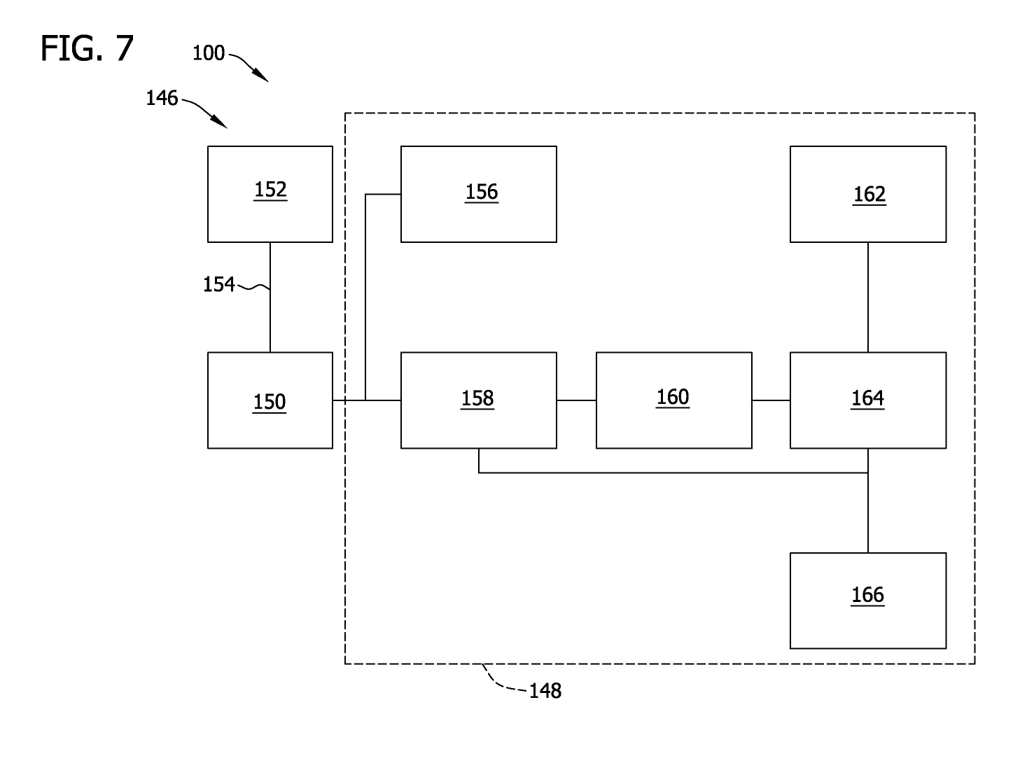

FIG. 7 is a schematic block diagram of an exemplary electrical architecture 146 of abdomen scanner system 100. In the exemplary embodiment, abdomen scanner system 100 includes modality 122, which is embodied using a quadrupole resonance (QR) detection system 148. System 100 also includes a computer 150 and an alarm 152 that is coupled to QR detection system 148 and computer 150 via a communications bus 154. In the exemplary embodiment, QR detection system 148 includes a radio frequency (RF) subsystem including an RF source 156, a pulse programmer and RF gate 158, and an RF power amplifier 160. RF source 156, pulse programmer and RF gate 158, and RF power amplifier 160 generate a plurality of RF pulses at a predefined frequency that are applied to a coil, such as an inductive sensor 162. A communication network 164 transmits the RF pulses from RF source 156, pulse programmer and RF gate 158, and RF power amplifier 160 to inductive sensor 162. Communication network 164 also transmits the RF pulses to from inductive sensor 162 to an RF detector 166.

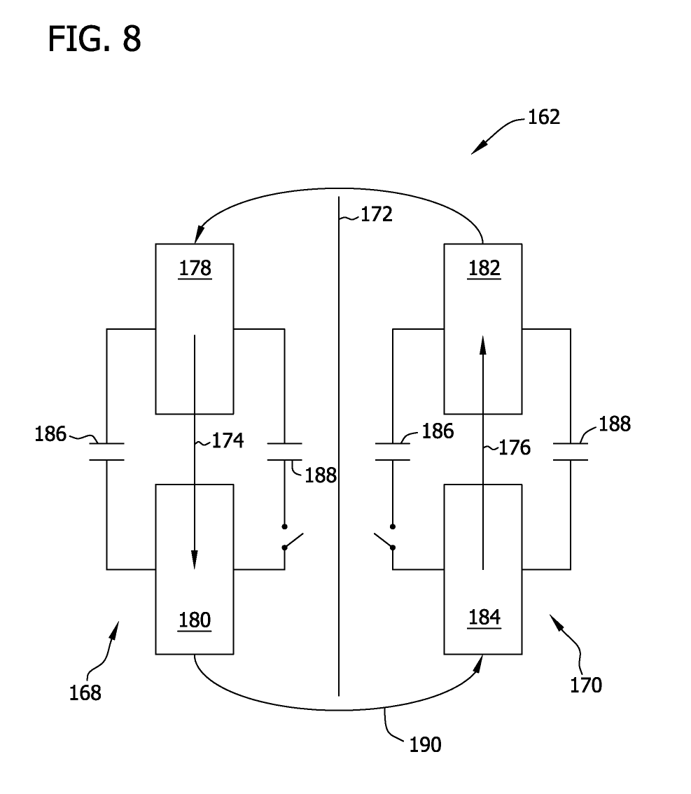

FIG. 8 is a schematic illustration of inductive sensor 162. In the exemplary embodiment, inductive sensor 162 is positioned in a recessed region (not shown) of platform 144 (shown in FIG. 1). Moreover, in the exemplary embodiment, inductive sensor 162 includes two anti-symmetrical current branches, namely a first current branch 168 and a second current branch 170, that are located on opposite sides of a medial plane 172 of abdomen scanner system 100. Each current branch 168 and 170 conducts current in a substantially parallel path to first and second walls 126 and 132 (both shown in FIG. 5). During operation, current flows through first current branch 168 in a first direction 174, and flows through second current branch 170 in a second direction 176 that is opposite first direction 174. In the exemplary embodiment, inductive sensor 162 operated at or near a normal human body temperature, i.e., approximately 37.0° C., as described above. In some embodiments, however, inductive sensor 162 is operated within a range of the normal human body temperature, such as plus or minus approximately six degrees Celsius. Accordingly, in the exemplary embodiment, inductive sensor 162 is operated at an operating frequency that is associated with the normal human body temperature.

As shown in FIG. 7, inductive sensor 162 is coupled to the RF subsystem, which provides electrical excitation signals to current branches 168 and 170. In some embodiments, the RF subsystem uses a variable frequency RF source to provide RF excitation signals at a frequency that generally corresponds to a predefined, characteristic nuclear quadrupole resonance (NQR) frequency of a target substance. During the screening process, the RF excitation signals generated by the RF subsystem are introduced to the passenger, including the lower abdomen and pelvic regions and/or the upper legs of the passenger, when the passenger is seated on platform 144. In the exemplary embodiment, inductive sensor 162 functions as a pickup coil for NQR signals generated by the passenger, thereby providing an NQR output signal that may be sampled to determine the presence of a target substance, such as an explosive material or other target substance, utilizing computer 150 (shown in FIG. 7).

In the exemplary embodiment, inductive sensor 162 utilizes an electromagnetic interference/radio frequency interference (EMI/RFI) shield to facilitate shielding sensor 162 from external noise and interference, and/or to facilitate inhibiting RFI from escaping from QR detection system 148 during the screening process. For example, in the exemplary embodiment, walls 126, 132, 138, and 140 (each shown in FIG. 5) perform RF shielding for inductive sensor 162. In one embodiment, walls 126, 132, 138, and 140 are electrically coupled to each other, to floor 142 (shown in FIG. 5), and to platform 144 to form an RF shield. In such an embodiment, each of walls 126, 132, 138, and 140, floor 142, and platform 144 are fabricated from a suitably conductive material, such as aluminum or copper. Moreover, walls 126, 132, 138, and 140, floor 142, and platform 144 maybe integrally formed or may be coupled together, such as welded together.

As shown in FIG. 8, first current branch 168 includes an upper conductive element 178 and a lower conductive element 180, which are separated by a non-conductive region. Similarly, second current branch 170 includes an upper conductive element 182 and a lower conductive element 184, which are separated by a non-conductive region. First and second current branches 168 and 170 collectively define inductive sensor 162, and may be formed from any suitable conductive material such as, but not limited to, copper and/or aluminum. Upper and lower conductive elements 178 and 180 are electrically coupled via a fixed-value resonance capacitor 186 and a tuning capacitor 188, which, in one embodiment, is a switched capacitor that is used to vary a tuning capacitance of inductive sensor 162. Upper and lower conductive elements 182 and 184 are similarly situated.

In the exemplary embodiment, current flows through first current branch 168 and second current branch 170 in a counter-clockwise direction, as shown by arrow 190. Accordingly, during operation, current flows through first current branch 168 in first direction 174, and flows through second current branch 170 in second direction 176 that is opposite to first direction 174. The current flows in such a manner due to different arrangements of positive and negative conductive elements in each current branch 168 and 170. For example, upper conductive element 178 is a positive conductive element and lower conductive element 180 is a negative conductive element. Conversely, upper conductive element 182 is a negative conductive element and lower conductive element 184 is a positive conductive element.

During operation, current flows between first and second current branches 168 and 170 since each is electrically coupled via a sensor housing. Moreover, during a scan, a passenger sits in abdomen scanner system 100 such that one side of the passenger is positioned over first current branch 168, and a second side of the passenger is positioned over second current branch 170 such that the passenger is bisected by medial plane 172. In such a scenario, current is directed oppositely through current branches 168 and 170 such that the current flows from a passenger back side to a passenger front side along first current branch 168, and flows from the passenger front side to the passenger back side along second current branch 170.

The embodiments described herein allow focused detection of contraband concealed in areas that may be difficult to examine using other screening methods, including a passenger's abdominal, pelvic and/or groin area, such as between the passenger's legs or inside a body cavity. In addition, the embodiments described herein use safe, non-ionizing radiation to target specific chemical components of contraband. Moreover, the embodiments described above can be combined with other passenger screening systems. As a result, a detection of contraband is improved and a time and area required for screening each passenger is reduced.

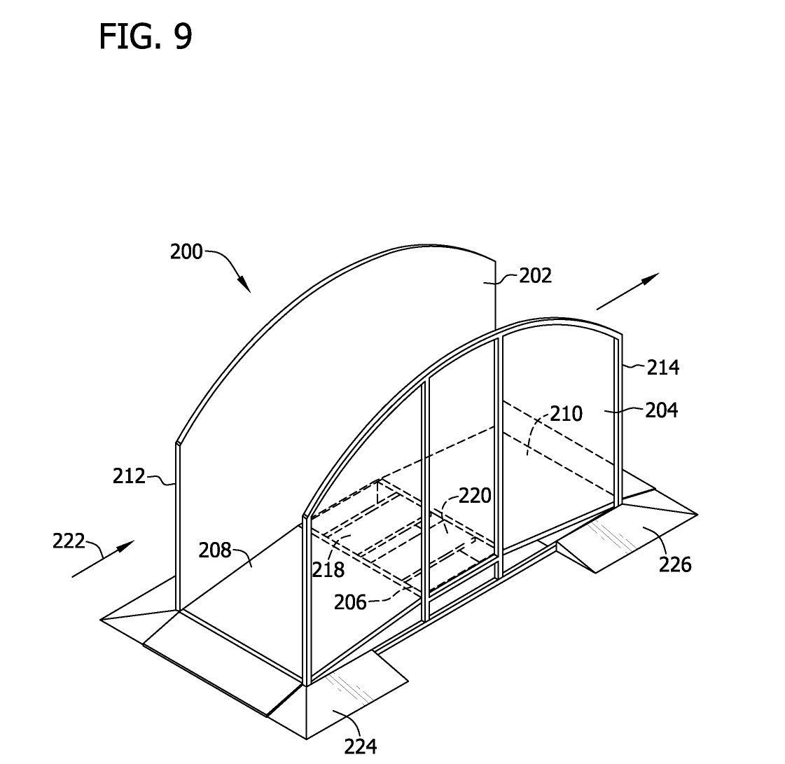

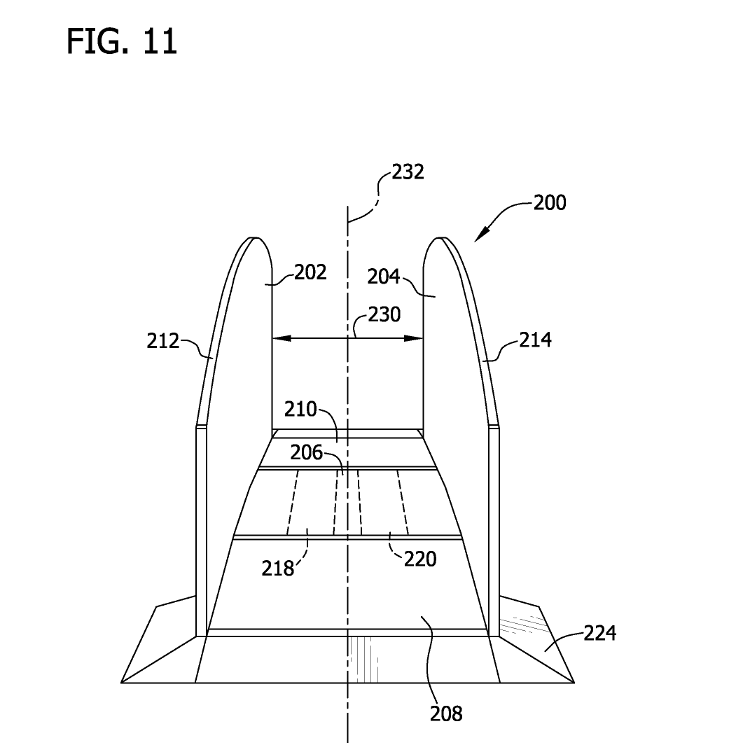

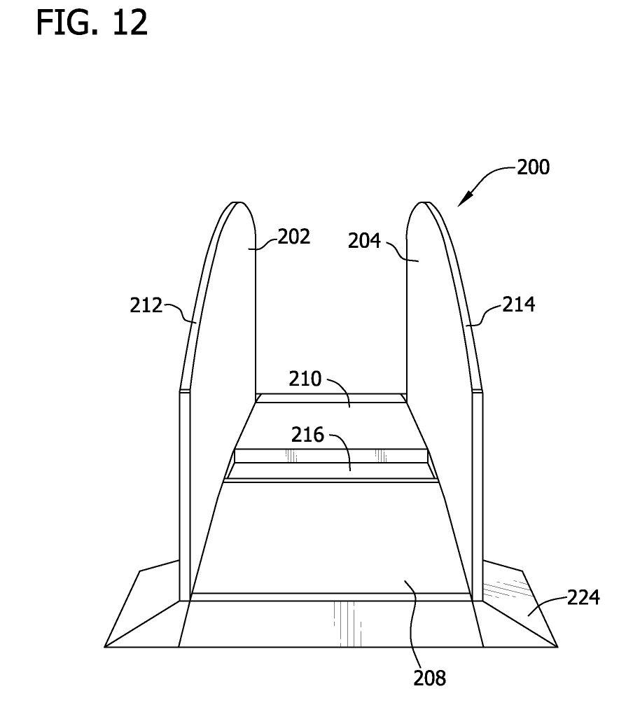

FIGS. 9-11 are perspective, side, and end-views, respectively, of a lower extremity scanner system 200. System 200 is shown embodied as a walkthrough shoe scanner and includes left wall 202 and right wall 204. Inductive sensor 206 is located between entrance ramp 208 and exit ramp 210. The left wall is supported by frame 212, and the right wall is supported by frame 214. In accordance with one embodiment, inductive sensor 206 may be positioned within a recessed region of the walkway, between the entrance and exit ramps. This recessed region will also be referred to as the sensor housing. In FIG. 12, inductive sensor 206 has been omitted to show sensor housing 216, which is recessed within the walkway of scanner system 200. In the exemplary embodiment, inductive sensor 206 is operated at or near a normal human body temperature, i.e., approximately 37.0° C. In some embodiments, however, inductive sensor 206 is operated within a range of the normal human body temperature, such as plus or minus approximately six degrees Celsius. Accordingly, in the exemplary embodiment, inductive sensor 206 is operated at an operating frequency that is associated with the normal human body temperature. In addition, inductive sensor 206 is operated within a range of operating frequencies that is associated with a range of temperatures that includes the normal human body temperature. As shown in FIGS. 9-11, inductive sensor 206 may be implemented using two anti-symmetric current branches 218 and 220. These current branches may be located on opposing sides of the medial plane of the inspection system. As shown in FIG. 11, current branch 218 is positioned on one side of medial plane 232, while current branch 220 is positioned on the opposite side of the medial plane.

Inductive sensor 206 may be configured in such a manner that both current branches experience current flow that is generally or substantially parallel to the left and right walls. For example, the current branches may be placed in communication with an electrical source (not shown in this figure). During operation, current flows through current branch 218 in one direction, while current flows through current branch 220 in substantially the opposite direction. The term “anti-symmetric current flow” may be used to refer to the condition in which current flows through the current branches in substantially opposite directions.

Inductive sensor 206 may be implemented using a quadrupole resonance (QR) sensor, a nuclear magnetic resonance (NMR) sensor, a metal detection sensor, and the like. For convenience only, various embodiments will be described with reference to the inductive sensor implemented as a QR sensor, but such description is equally applicable to other types of inductive sensors. Referring still to FIGS. 9-11, current branches 218 and 220 collectively define a QR sheet coil or a QR tube array coil. For convenience only, further discussion of the QR sensor will primarily reference a “QR sheet coil,” or simply a “QR coil,” but such description applies equally to a QR tube array coil. During a typical inspection process, a person enters the system at entrance 222, and then stands within an inspection region defined by QR sensor 206. In one embodiment, the person may stand with their left foot positioned relative to current branch 218 and their right foot positioned relative to current branch 220. The QR sensor then performs an inspection process using nuclear quadrupole resonance (NQR) to detect the presence of a target substance associated with the person. In general, QR sensor 206 includes, or is in communication with, an RF subsystem which provides electrical excitation signals to current branches 218 and 220. Using well-known techniques, the RF subsystem may utilize a variable frequency RF source to provide RF excitation signals at a frequency generally corresponding to a predefined, characteristic NQR frequency of a target substance. During the inspection process, the RF excitation signals generated by the RF source may be introduced to the specimen, which may include in certain embodiments the shoes, socks, and clothing present on the lower extremities of a person standing or otherwise positioned relative to the QR sensor. In some embodiments, the QR coil may serve as a pickup coil for NQR signals generated by the specimen, thus providing an NQR output signal which may be sampled to determine the presence of a target substance, such as an explosive.

As with other types of inductive sensors, QR sensor 206 typically requires some degree of electromagnetic interference/radio frequency interference (EMI/RFI) shielding from external noise. In addition, the QR sensor may also need shielding which inhibits RFI from escaping from the inspection system during an inspection process. The best RFI shielding is normally an electrically connected and grounded box that completely encloses the RF coil of the QR sensor. This arrangement prevents external noise from directly reaching the RF coil. Another common shielding technique is to position the RF coil within an enclosure having a wave-guide tunnel extension. However, these solutions are not always practical for inspecting humans, for example, since some people are wary or uncomfortable about having to walk and stand in confined spaces.

FIGS. 9-12 show one example of a passive, open-access RF shield which may be used in conjunction with a QR sensor. Shielding for system 200 may be accomplished by electrically connecting left and right walls 202 and 204, entrance and exit ramps 208 and 210, and sensor housing 216. Each of the shielding components may be formed from a suitably conductive material, such as aluminum and/or copper. Typically, the floor components (ramps 208 and 210, and sensor housing 216) are welded together to form a unitary structure. The left and right walls may also be welded to the floor components, or secured using suitable fasteners such as bolts, rivets, screws and/or pins. QR sensor 206 may be secured within sensor housing 216 using, for example, any suitable fasteners and/or fastening techniques as described above. The left and right walls, entrance and exit ramps, and the sensor housing collectively define a substantially V-shaped shielded structure which provides a walkway through which persons may pass during an inspection process.

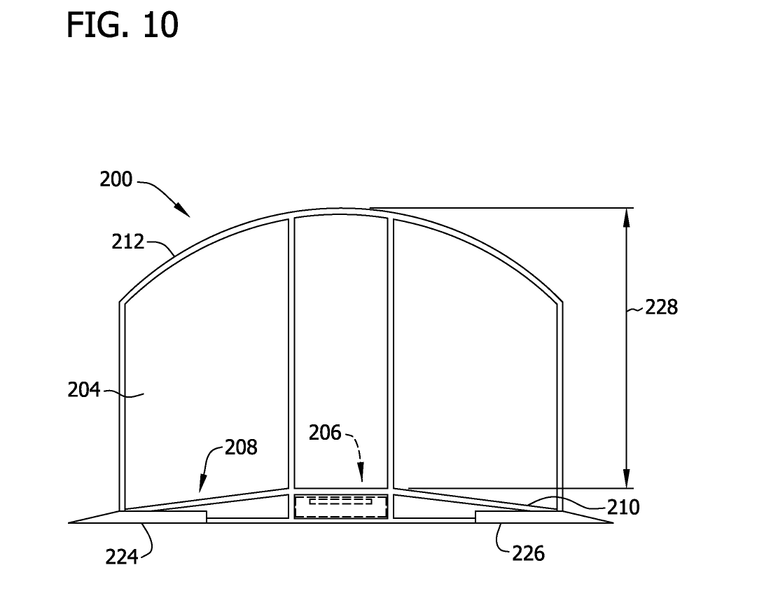

In some embodiments, the left and right walls, the entrance and exit ramps, and the QR sensor may be covered with non-conducive materials, such as wood, plastic, fabric, fiberglass, and/or the like. System 200 is shown having optional entrance and exit surrounds 224 and 226. These surrounds facilitate the ingress and egress of people walking through the inspection system. In some embodiments, the overall size and shape of system 200 is sufficient to provide the necessary electromagnetic shielding for the inductive sensor being implemented (for example, QR sensor 206). FIG. 10 shows left and right walls 202 and 204 having an overall height 228. This height is defined as the distance between a top surface of QR sensor 206 and the highest portion of the respective wall. System 200 has a width 230, which is defined by the distance between walls 202 and 204. FIG. 11 shows system 200 having a medial plane 232, which is approximately parallel to the walls of system 200. The embodiment of FIGS. 9-12 show the left and right walls formed with an approximate arcuate shape having a radius which approximates the height of the walls. Note that the walls have been optionally truncated at the entrance and exit. Truncating the walls facilitates the movement of people through the system, and further extends the notion of openness of the system.

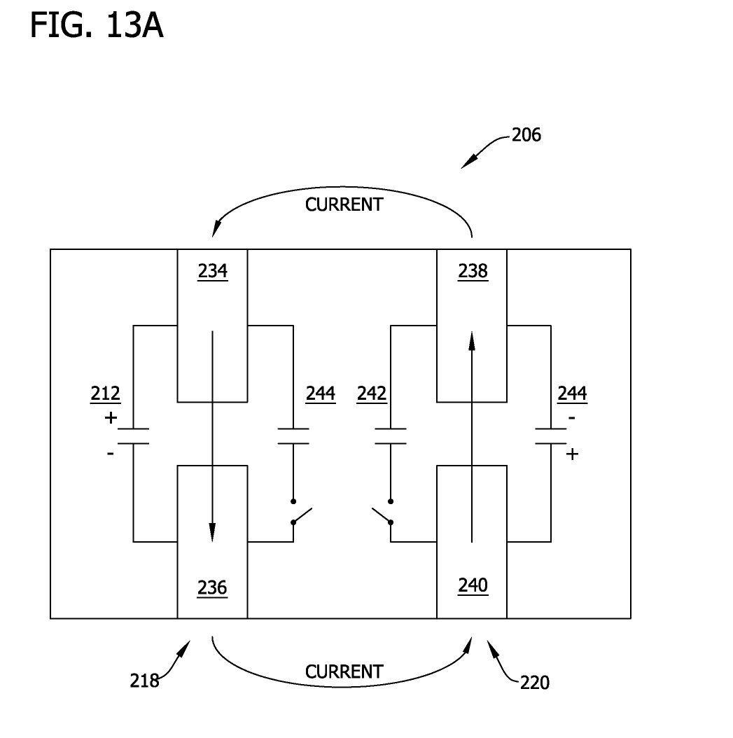

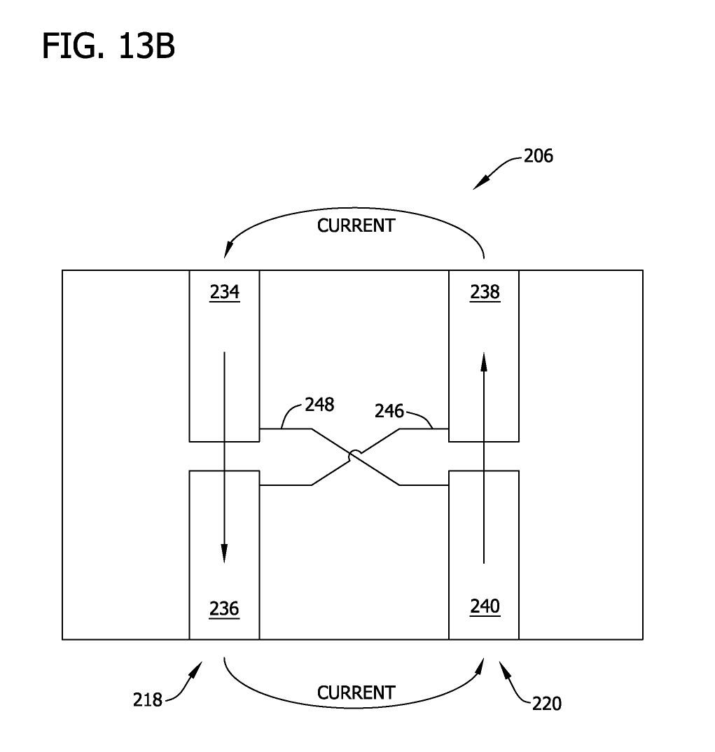

FIG. 13A is a simplified schematic diagram depicting some of the primary electrical components of QR sensor 206. Left current branch 218 is shown having upper and lower conductive elements 234 and 236, which are separated by a non-conductive region. Similarly, right current branch 220 includes upper and lower conductive elements 238 and 240, which are also separated by a non-conductive region. The left and right current branches collectively define the QR coil of the sensor, shown in FIGS. 9 and 11, and may be formed from any suitably conductive material, such as copper and/or aluminum, for example. Upper and lower conductive elements 234 and 236 are shown electrically coupled by fixed-valued resonance capacitor 242 and tuning capacitor 244, which is a switched capacitor that is used to vary tuning capacitance. Upper and lower conductive elements 238 and 240 may be similarly configured.

FIG. 13A also includes several arrows which show the direction of current flow through the left and right current branches. During operation, current flows through left current branch 218 in one direction, while current flows through right current branch 220 in substantially the opposite direction. The reason that current flows through the two current branches in opposite directions is because the left and right current branches have a different arrangement of positive and negative conductive elements. For instance, left current branch 218 includes a positive upper conductive element 234 and a negative lower conductive element 236. In contrast, right current branch 220 includes a negative upper conducive element 238 and a positive lower conductive element 240. This arrangement is one example of a QR sensor providing counter-directed or anti-symmetric current flow through the current branches. In one embodiment, current flows between the left and right current branches during operation since these components are electrically coupled via ramps 208 and 210, and the sensor housing 216. During operation, a person may place his or her left foot over left current branch 218 and his or her right foot over right current branch 220. In such a scenario, current is directed oppositely through each branch resulting in current flowing from toe to heal along left current branch 218, and from heal to toe along right current branch 220.

FIG. 13B is a simplified schematic diagram depicting optional current balance wires in communication with the left and right current branches of QR sensor 206. Note that FIG. 13B depicts the same QR sensor of FIG. 13A, but fixed-valued resonance capacitor 242 and tuning capacitor 244 of the left and right current branches have been omitted for clarity. In FIG. 13B, current balance wire 246 is shown electrically coupling upper conductive element 238 and lower conductive element 236. Current balance wire 248 similarly couples lower conductive element 240 and upper conductive element 234. The balance wires assist the QR sensor in maintaining the above-described anti-symmetric flow of current through current branches 218 and 220. In addition, these current branches enable the positive and negative terminals of left and right current branches 218 and 220 to maintain the same, or substantially the same, current level.

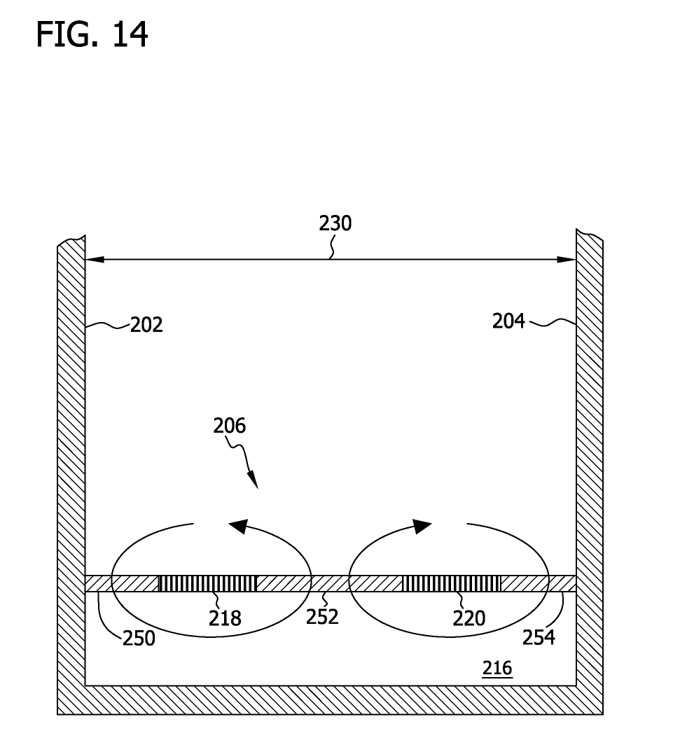

FIG. 14 is a partial cross-sectional view of QR inspection system 200, showing QR sensor 206 positioned within sensor housing 216. Left current branch 218 is shown producing a magnetic field which circulates in a counterclockwise direction about the current branch. In contrast, right current branch 220 produces a magnetic field which circulates in a clockwise direction about the current branch. The direction of the magnetic fields generated by each current branch results from the particular direction of the current flowing through each respective branch. Since the current flows through each branch in opposite directions, as shown in FIGS. 13A and 13B, the magnetic fields generated by each of these branches likewise circulate in opposite directions. The QR sensor shown in FIG. 14 produces counter-directed magnetic fields which individually circulate about left or right current branches 218 and 220. In the embodiment of FIG. 14, the QR sensor is implemented using a printed circuit board (PCB). The left and right current branches are electrically isolated from each other, and from conductive walls 202 and 204, by non-conductive regions 250, 252, and 254. These non-conductive regions permit the magnetic fields to circulate about their respective current branches.

Operation of an exemplary walkthrough QR inspection system may proceed as follows. First, a person may be directed to enter QR inspection system 200 at entrance 222. The person proceeds up entrance ramp 208 and stands with his or her feet positioned over QR sensor 206. To maximize the accuracy of the inspection process, the person will stand with his or her left foot positioned over left current branch 218 and his or her right foot over right current branch 220. At this point, the lower extremities of the person are QR scanned by QR sensor 206 to determine the presence of a target substance. This may be accomplished by the QR sensor providing RF excitation signals at a frequency generally corresponding to a predefined, characteristic NQR frequency of the target substance. When acting as a pickup coil, QR sensor 206 may then detect any NQR signals from the target specimen. These signals may be communicated to a suitable computing device for processing and analysis, as will be described in more detail below. In some embodiments, QR sensor 206 may be designed to detect a change or shift in the QR tune frequency resulting from the presence of a conductive object, such as a knife, located at or in proximity to the lower extremities of the inspected person.

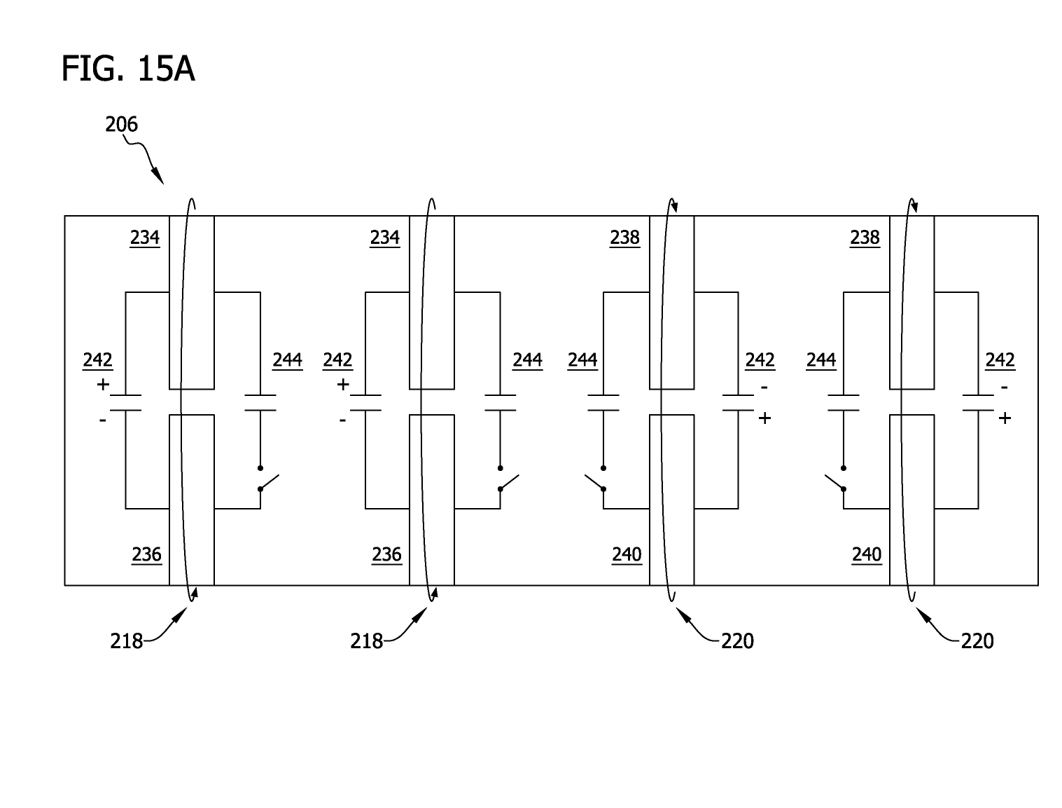

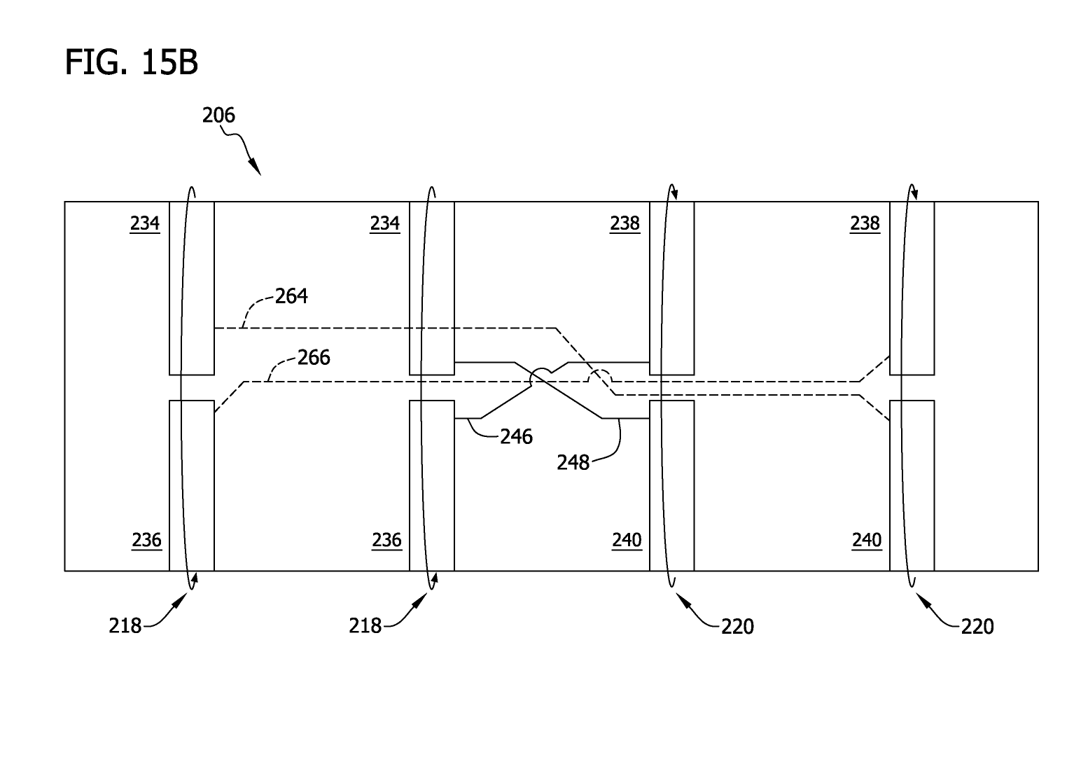

FIG. 15A is a simplified schematic diagram depicting some of the primary electrical components of an alternative QR sensor 206. Similar to other embodiments, QR sensor 206 may be sized to be received within sensor housing 216 of the inspection system. As such, two current branches 218 may be positioned on one side of medial plane 232 of the inspection system (shown in FIG. 11), and two current branches 220 may be positioned on the opposing side of the medial plane. For ease of discussion, the two sides of the medial plane will sometimes be referred to as the left and right sides. Both current branches 218 are shown having upper and lower conductive elements 234 and 236, and both current branches 220 have upper and lower conductive elements 238 and 240. FIG. 15A also includes several arrows which show the direction of current flow through the various current branches of the QR sensor. During operation, current flows through the left-two current branches 218 in one direction, while current flows through the right-two current branches 220 in substantially the opposite direction. As described above, the current flows through the current branches in opposite directions because the left-two and the right-two current branches have a different arrangement of positive and negative conductive elements.

FIG. 15B is a simplified schematic diagram depicting optional current balance wires in communication with the various current branches of QR sensor 206. Note that FIG. 15B depicts the same QR sensor of FIG. 15A, but fixed-valued resonance capacitor 242 and tuning capacitor 244 of the various current branches have been omitted for clarity. In FIG. 15B, current balance wire 264 is shown electrically coupling upper conductive element 234 of the outer current branch 218 with lower conductive element 240 of the outer current branch 220. Current balance wire 266 similarly couples lower conductive element 236 of the outer current branch 218 with upper conductive element 238 of the outer current branch 220. The balance wires assist the QR sensor in maintaining the anti-symmetric flow of current between the right-two current branches 218 and the right-two current branches 220. In addition, these current branches enable the connected conductive elements to maintain the same, or substantially the same, current level.

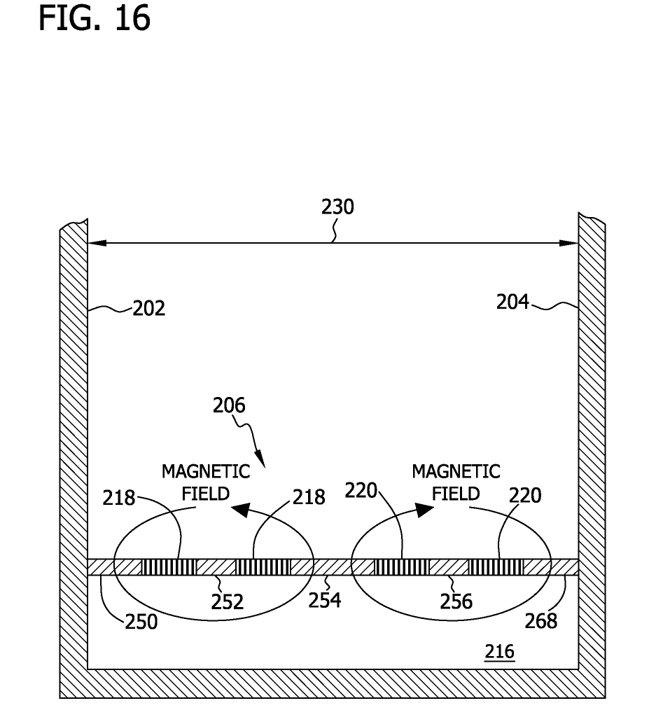

FIG. 16 is a partial cross-sectional view of QR inspection system 200, showing QR sensor 206 positioned within sensor housing 216. The left-two current branches 218 are shown collectively producing a magnetic field which circulates in a counter-clockwise direction about these two current branches. In contrast, the right-two current branches 218 collectively produce a magnetic field, which circulates in a clockwise direction about these two current branches. The right-two current branches 220 cooperate to generate a single magnetic field which circulates about both of these current branches. Accordingly, the QR sensor shown in FIG. 16 produces counter-directed magnetic fields using a plurality of adjacent current branches having current flow in one direction, and a plurality of adjacent current branches having current flow in substantially the opposite direction. For example, FIG. 16 shows QR sensor 206 utilizing two adjacent current carrying branches to produce magnetic fields in one of the two illustrated directions. If desired, the QR sensor may alternatively implement three or more adjacent current carrying branches to produce a magnetic field in a particular direction.

In the embodiment of FIG. 16, the various current branches are electrically isolated by non-conductive regions 250, 252, 254, 256, and 268. Operation of a walkthrough QR inspection system in accordance with the embodiment of FIG. 16 may proceed as follows. First, a person may be directed to enter QR inspection system 200 at entrance 222. The person proceeds up entrance ramp 208 and stands within the inspection region defined by QR sensor 206. In some embodiments, the person will stand with his or her left foot positioned over the left-two current branches 218 and his or her right foot over the right-two current branches 220. At this point, the lower extremities of the person may be QR scanned by QR sensor 206 to determine the presence of a target substance using any of the techniques previously described.

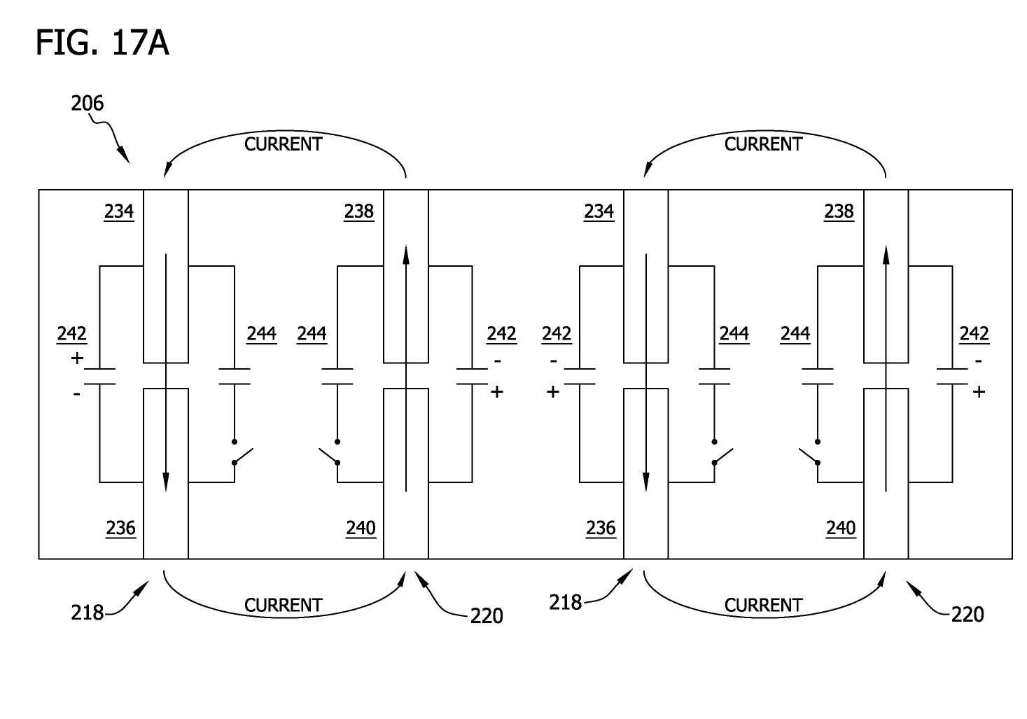

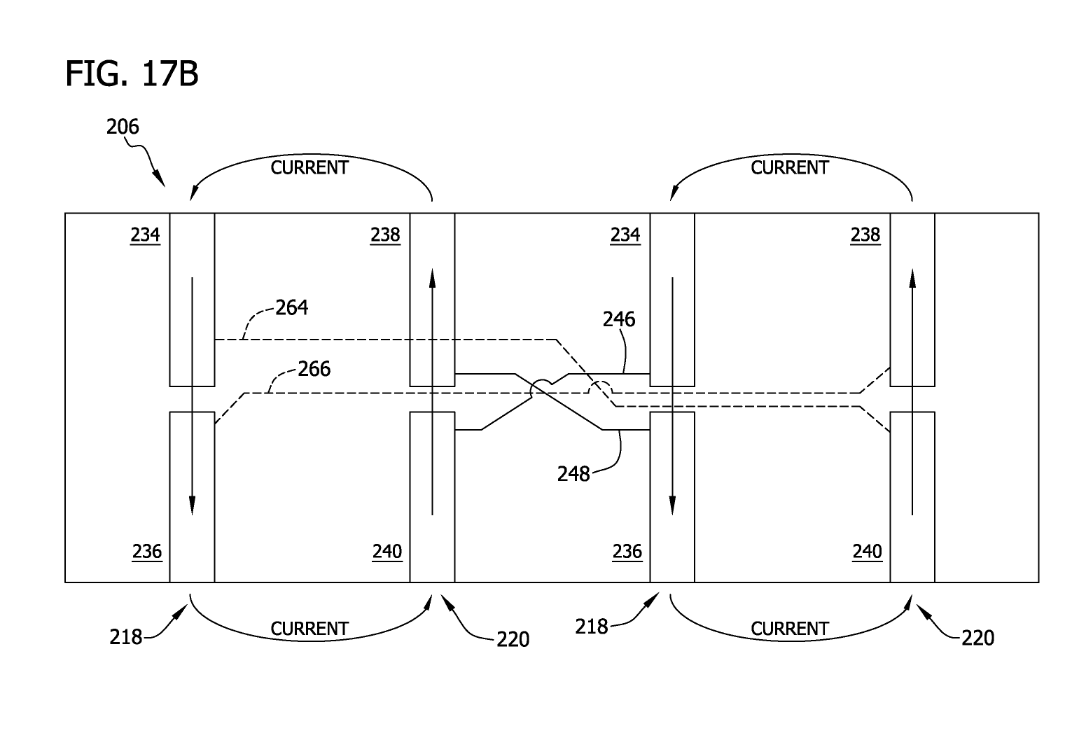

FIG. 17A is a simplified schematic diagram depicting some of the primary electrical components of an alternative QR sensor 206. QR sensor 206 is similar in many respects to QR sensor 206 of FIG. 15A. The primary distinction relates to the arrangement of the four current branches of the sensor. QR sensor 206 of FIG. 15A has two adjacent current branches 218 positioned at the left side of the sensor, and two adjacent current branches 220 positioned at the right side of the sensor. In contrast, QR sensor 206 of FIG. 17A utilizes adjacent current branches which have current flow in alternating directions. For example, looking from left to right, QR sensor 206 includes the following series of current branches, such as two first current branches 218 and two second current branches 220. Current flows through each first current branch 218 in one direction, and through each second current branch 220 in another direction. FIG. 17B is a simplified schematic diagram depicting optional current balance wires in communication with the various current branches of QR sensor 206. FIG. 17B depicts the same QR sensor of FIG. 17A, but fixed-valued resonance capacitor 242 and tuning capacitor 244 of the various current branches have been omitted for clarity. Similar to other embodiments, balance wires 246, 248, 264, and 266 electrically couple their respective conductive elements.

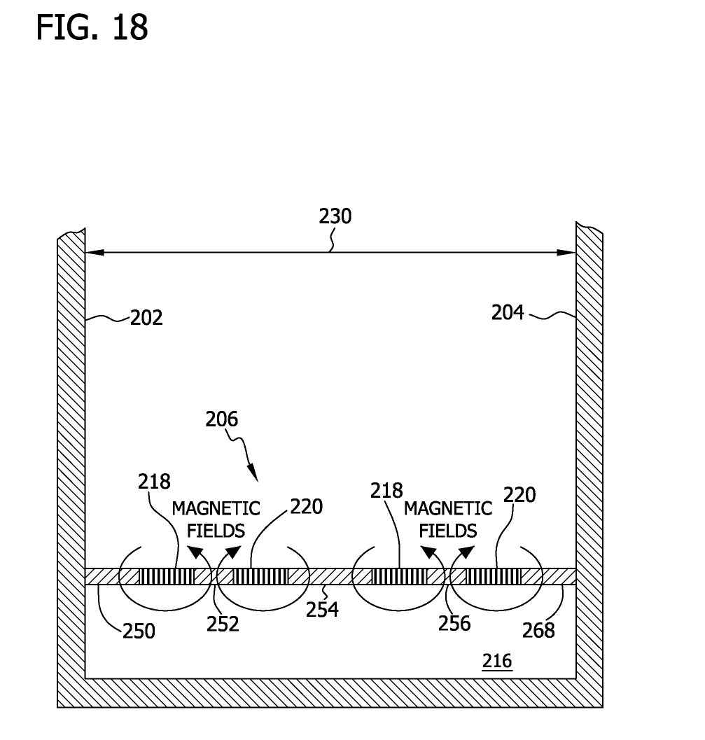

FIG. 18 is a partial cross-sectional view of QR inspection system 200, showing QR sensor 206 positioned within sensor housing 216. On the left side of the QR inspection system, current branch 218 produces a magnetic field which circulates in a counter-clockwise direction, and adjacent current branch 220 produces a magnetic field which circulates in a clockwise direction. The two current branches on the right side of the QR inspection system may be similarly configured to produce magnetic fields. If desired, the embodiment of FIG. 18 may be modified to include additional pairs of current carrying branches. The embodiment of FIG. 18 is an example of a QR sensor having a plurality of current branches having current flow in one direction, and a plurality of current branches having current flow in substantially the opposite direction. Operation of QR sensor 206 may proceed in a manner similar to that described in other embodiments. Note that the alternating current branch arrangement of QR sensor 206 provides a certain degree of sensitivity for conductive objects, permitting the detection of such objects in orientations which may not be possible by the QR sensors of other embodiments. As such, the QR sensor arrangement of FIG. 18 may be used to augment or replace other types of QR sensors disclosed herein.

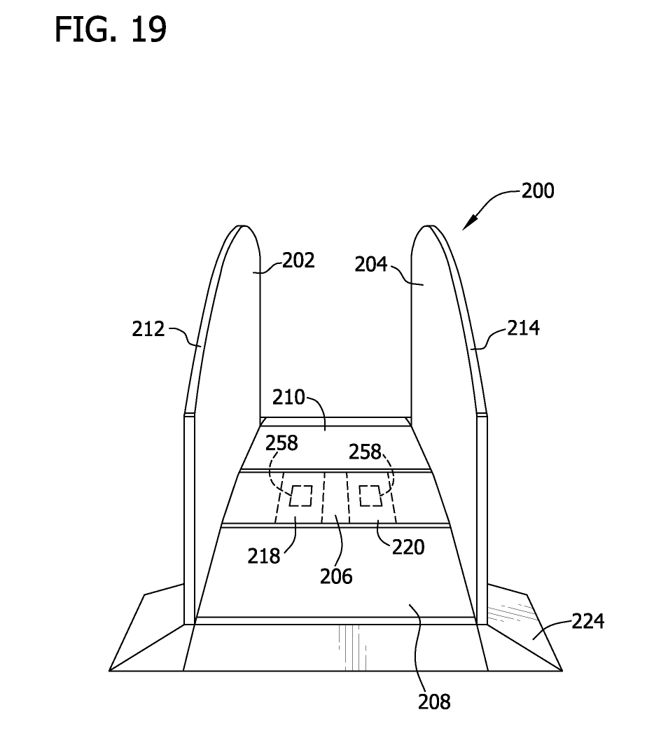

As described above, the QR sensor may be configured to detect metallic objects in a number of different orientations. To enhance the metal detection capability of inspection system 200, the inspection system may alternatively or additionally include a separate metal detection sensor. One example of such a system is shown in FIG. 19. In FIG. 19, inspection system 200 is shown having metal detection sensors 258 in association with QR sensor 206. Each of the metal detection sensors may be configured to detect conductive objects present at or within the vicinity of the lower extremities of the inspected person. Any variety of known metal detection sensors may be used.

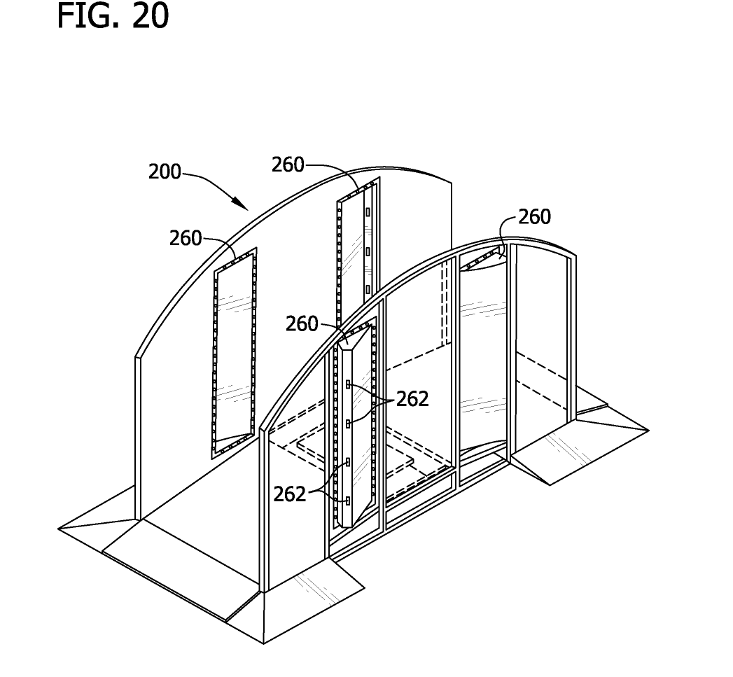

FIG. 20 is a perspective view of QR inspection system 200, which contains a QR sensor 206 (not shown in this figure). System 200 is similar in many respects to QR inspection system 200, which is shown in FIG. 9. One distinction is that system 200 has been adapted to operate in conjunction with a portal detection system. In particular, system 200 includes four nozzle interfaces 260 which are individually formed within the walls of the QR inspection system. Each interface includes four nozzle apertures 262, which are sized to receive a linear jet array (not shown in this figure). Typically, the nozzle interfaces are welded, bolted, or otherwise attached or formed within their respective walls and may be constructed using the same conductive materials as the walls.

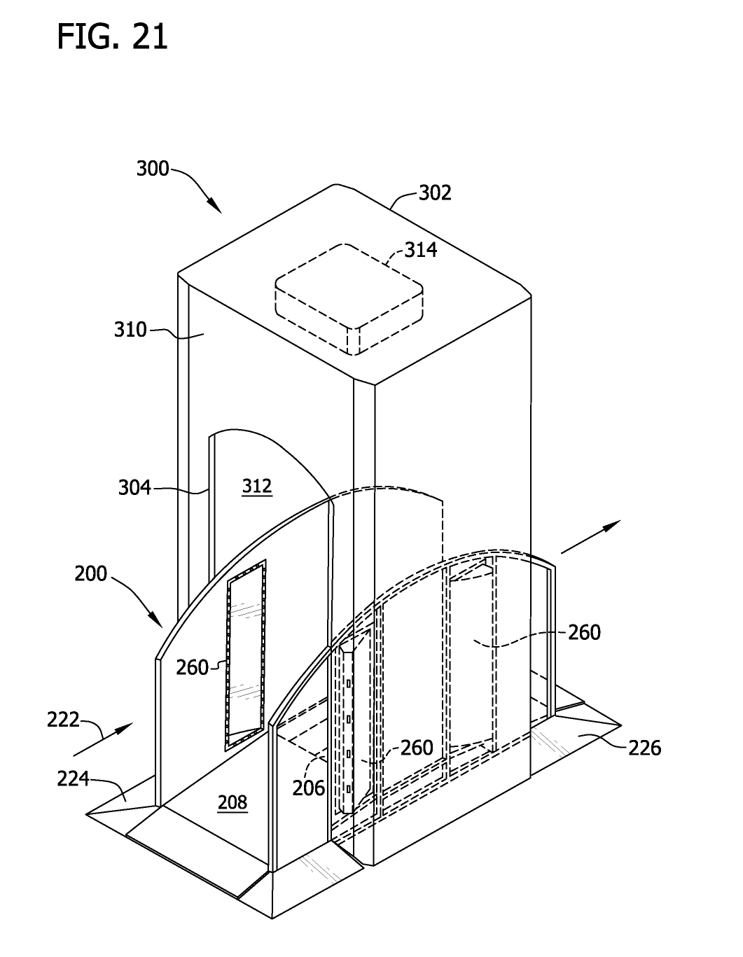

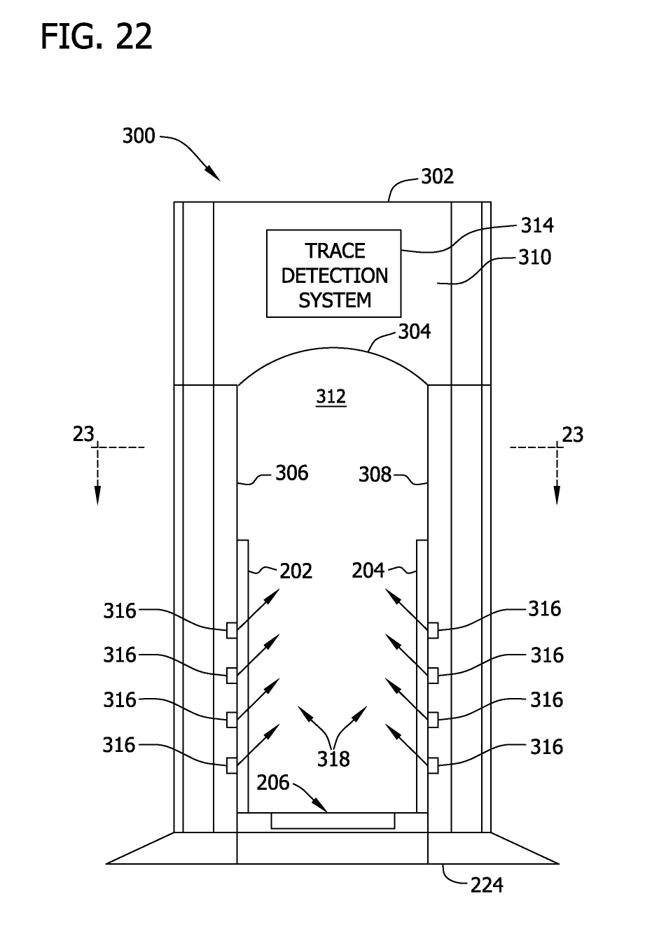

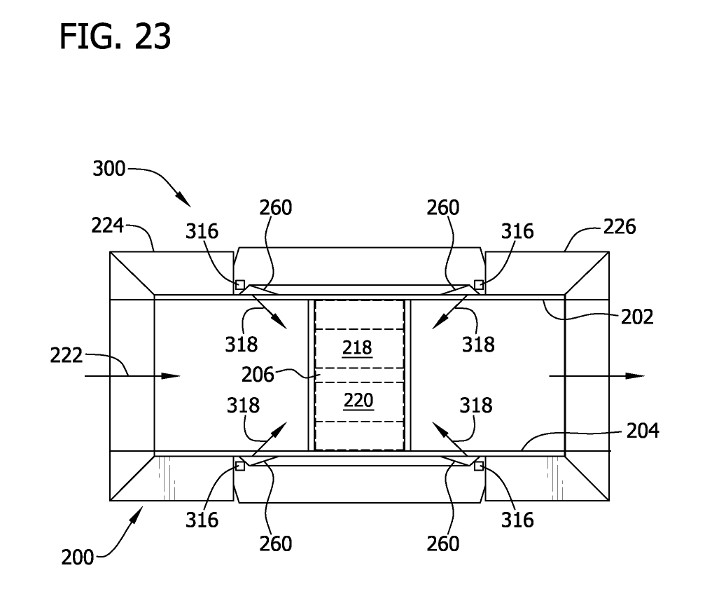

FIGS. 21 and 22 are perspective and end-views, respectively, of multi-sensor inspection system 300. FIG. 23 is a cross-sectional view of the multi-sensor inspection system taken along line 15-15 of FIG. 22. The multi-sensor inspection system includes walkthrough QR inspection system 200 configured in association with portal detection system 302. Portal detection system 302 includes portal 304 having sidewalls 306 and 308, a plastic ceiling or hood 310, and passage 312 extending between the sidewalls and beneath the ceiling. The ceiling may include an inlet with a fan for producing air flow that substantially matches the air flow rate provided by the human thermal plume. During operation, particles of interest will be entrained in the human thermal plume that exists in the boundary layer of air adjacent the inspected person, and will flow upwardly from the person to the detection apparatus in the ceiling of the portal. The ceiling further includes trace detection system 314, which is a system capable of detecting minute particles of interest such as traces of narcotics, explosives, and other contraband. System 314 may be implemented using, for example, an ion trap mobility spectrometer. If desired, portal detection system 302 may further include a plurality of air jets 316. The jets are arranged to define four linear jet arrays 318 (FIG. 23) with the jets in each array being vertically aligned. The jets may be disposed in portal 304 to extend from a lower location approximately at knee level to an upper location approximately at chest level. Each jet may be configured to direct a short puff of air inwardly and upwardly into passage 312 of the portal. The jets function to disturb the clothing of the human subject in the passage sufficiently to dislodge particles of interest that may be trapped in the clothing of the inspected person. However, the short puffs of air are controlled to achieve minimum disruption and minimum dilution of the human thermal plume. The dislodged particles then are entrained in the human thermal plume that exists adjacent the human subject. Air in the human thermal plume, including the particles of interest that are dislodged from the clothing, is directed to trace detection system 314 for analysis.

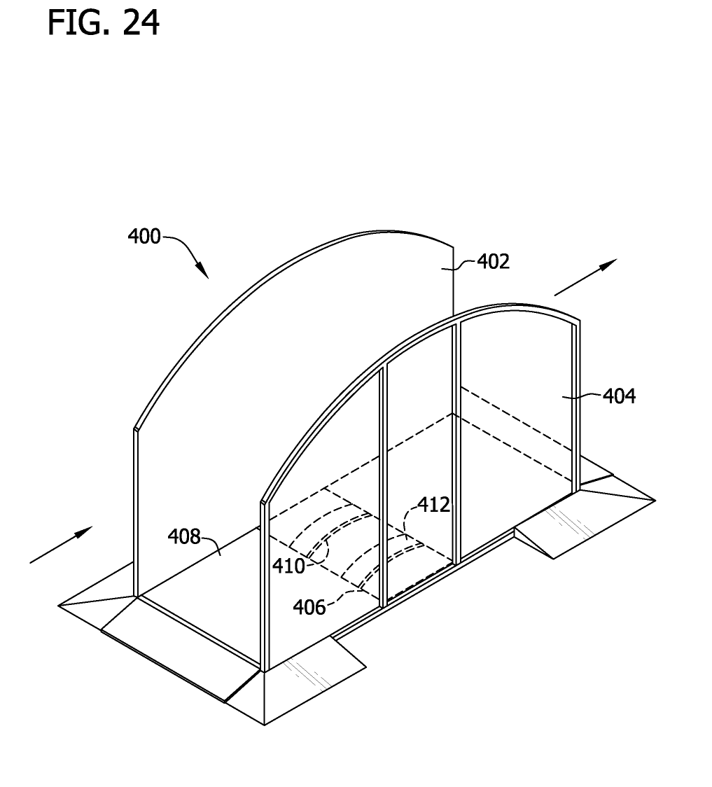

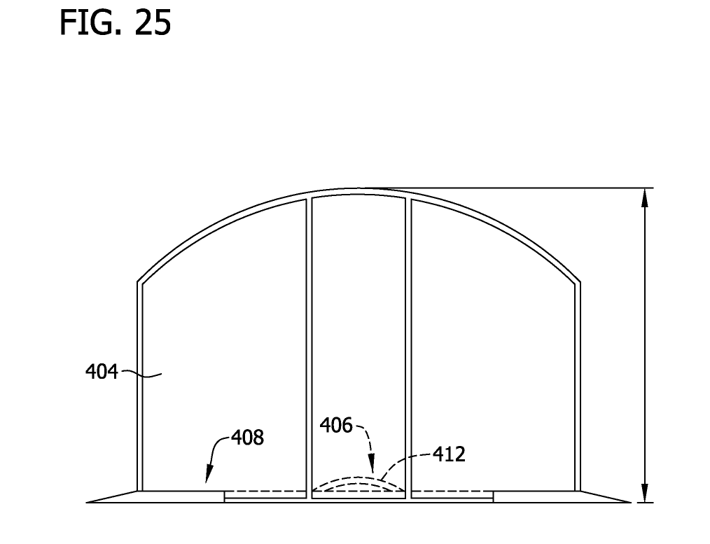

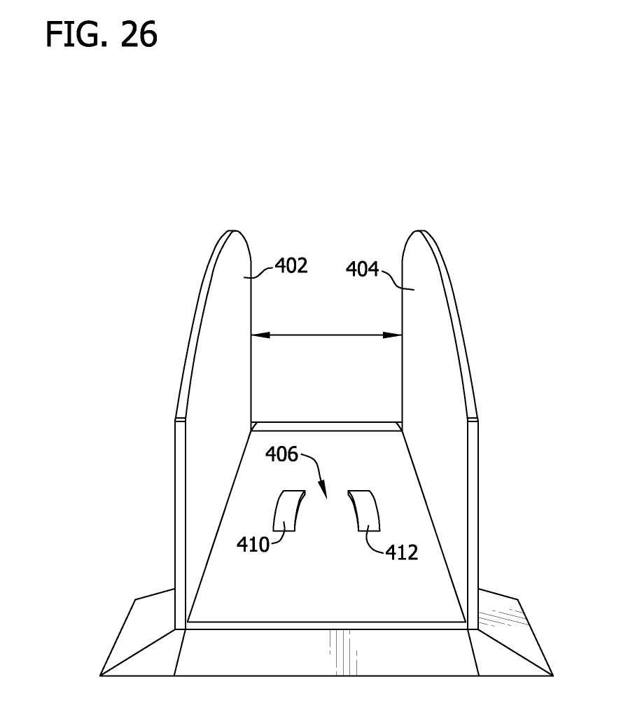

FIGS. 24-26 are perspective, side, and end-views, respectively, of inspection system 400. Similar to other embodiments, inspection system 400 includes walls 402 and 404, and an inductive sensor 406 positioned within a walkway defined by the walls. As described above, the inductive sensor is shown implemented as a QR sensor, but other types of inductive sensors may alternatively be used. In contrast to the inclined ramp arrangement of the inspection system of FIGS. 9-11, system 400 includes floor 408, which defines a substantially flat walkway between walls 402 and 404. In this embodiment, QR sensor 406 includes current branches 410 and 412 which protrude from the floor of the inspection system. The protruding current branches do not require a recessed sensor housing. In general, the current branches of QR sensor 406 operate in a manner similar to that described above. However, QR sensor 406 provides additional functionality which will be described in more detail below. Electromagnetic shielding for the inspection system may be accomplished by electrically connecting floor 408 with left and right walls 402 and 404. Each of these components of the shield may be formed from a suitably conductive material, such as aluminum and/or copper. The left and right walls may also be welded to the floor component, or secured using any of the previously described techniques. If desired, the left and right walls, the floor, and the QR sensor may be covered with non-conducive materials, such as wood, plastic, fabric, fiberglass, and/or the like.

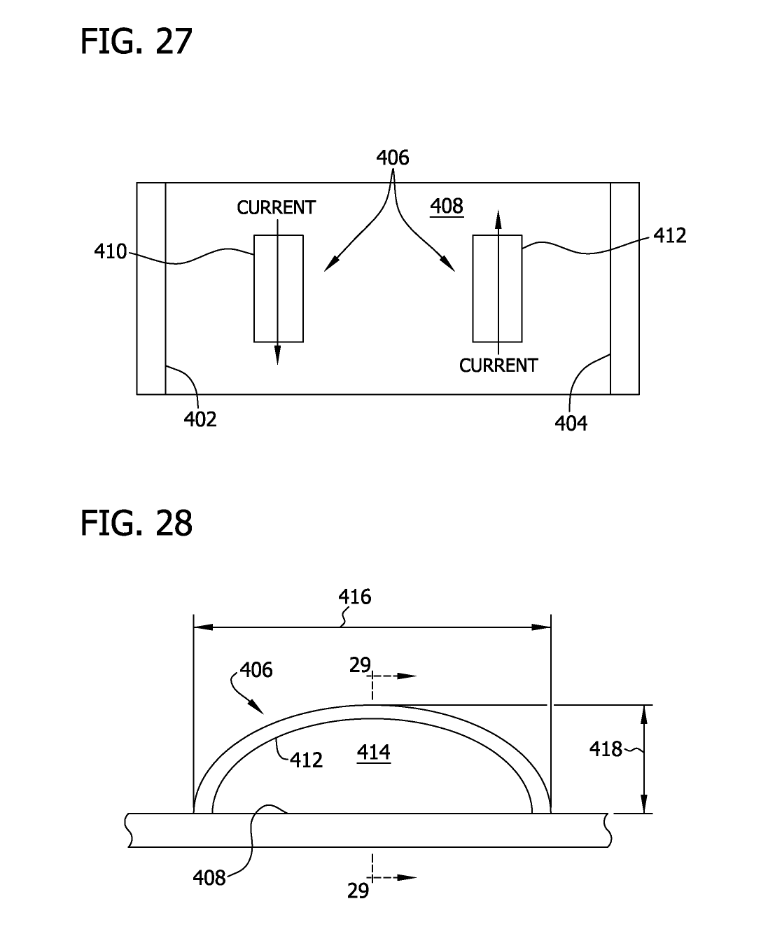

FIG. 27 is a top view of a portion of inspection system 500, showing the relative positioning of left and right current branches 410 and 412. Similar to other embodiments, current branches 410 and 412 have anti-symmetric current flow.

FIG. 28 is a side view of QR sensor 406, which is in electrical communication with floor 408. Only right current branch 412 is visible in this figure, but left current branch 410 may be similarly dimensioned and positioned. The right current branch is shown having a generally arcuate shape which forms gap 414. The gap is defined by the region between the bottom of the current branch and the top of floor 408. The current branch has length 416 and height 418. No particular length or height is required, but in general, the length of the current branches is such that they are slightly longer than the object or specimen being inspected.

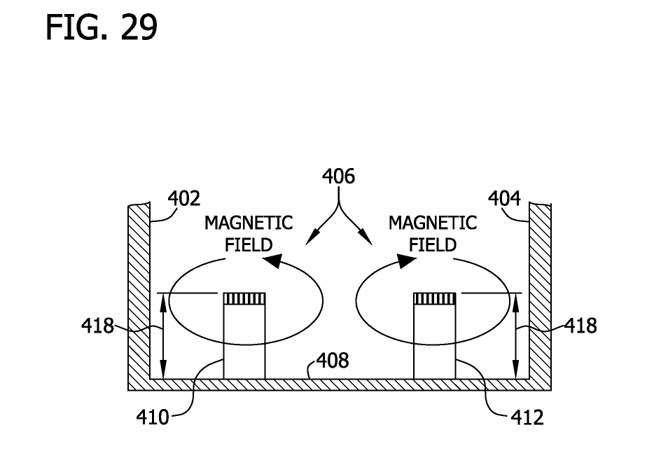

FIG. 29 is a partial cross-sectional view of QR inspection system 400, showing QR sensor 406 in electrical communication with floor 408. The left and right current branches 410 and 412 are shown producing counter-directed magnetic fields which individually circulate about their respective current branches. In other embodiments, a recess was formed in the floor of the inspection system to form a gap which allowed the magnetic fields to circulate. Such a recess is not necessary for system 400. Instead, the left and right current branches may be structured so that that they each form gap 414, which defines a non-conductive region between the current branch and floor 408. This non-conductive region or gap permits the magnetic fields to circulate about their respective current branches. Another benefit provided by system 400 is that the inspection of a correspondingly higher location of the lower extremities of the inspected person may be accomplished. This is because the left and right current branches protrude from the floor of the inspection system, thus allowing the generated magnetic fields to engage the inspected person at a location which is further from the floor of the inspection station.

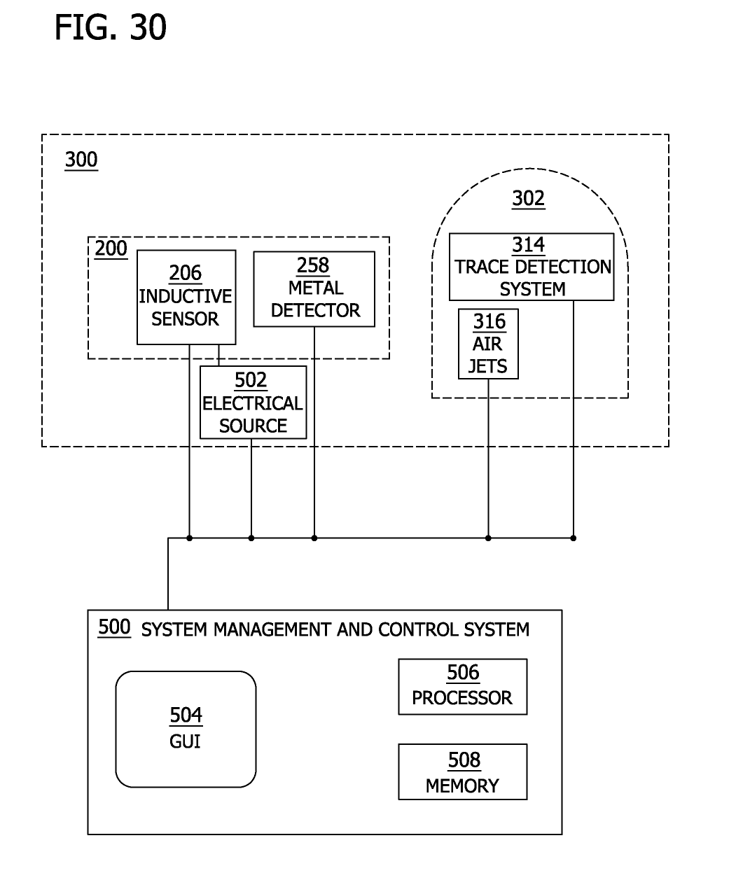

FIG. 30 is block diagram of system 500, which may be implemented to control, manage, operate, and monitor, the various components associated with multi-sensor system 300. Note that description of system 500 will be made with reference to metal detector 258, trace detection system 314, and air jets 316, which are all optional components. In addition, FIG. 30 will be described with reference to inspection system 300, but such description applies equally to the other inspection systems and various inductive sensors described herein. System 500 is shown having a graphical user interface 504, processor 506, and memory 508. The processor may be implemented using any suitable computational device that provides the necessary control, monitoring, and data analysis of the various systems and components associated with the various inspection and detector systems, including electrical source 502.

In general, processor 506 may be a specific or general purpose computer such as a personal computer having an operating system such as DOS, Windows, OS/2 or Linux; Macintosh computers; computers having JAVA OS as the operating system; graphical workstations such as the computers of Sun Microsystems and Silicon Graphics, and other computers having some version of the UNIX operating system such as AIX or SOLARIS of Sun Microsystems; or any other known and available operating system, or any device including, but not limited to, laptops and hand-held computers. Graphical user interface 504 may be any suitable display device operable with any of the computing devices described herein and may include a display, such as an LCD, LED, CRT, plasma monitor, and the like.

The communication link between system 500 and the various inspection and detector systems may be implemented using any suitable technique that supports the transfer of data and necessary signaling for operational control of the various components (for example, inductive sensor 206, metal detector 258, trace detection system 314, air jets 316) of the multi-sensor inspection system. The communication link may be implemented using conventional communication technologies such as UTP, Ethernet, coaxial cables, serial or parallel cables, and optical fibers, among others. Although the use of wireless communication technologies is possible, they are typically not utilized because they may not provide the necessary level of security required by many applications, such as airport baggage screening systems. In some implementations, system 500 is physically configured in close physical proximity to the inspection system, but system 500 may be remotely implemented if desired. Remote implementations may be accomplished by configuring system 500 and the inspection system with a suitably secure network link that includes a dedicated connection, a local area network (LAN), a wide area network (WAN), a metropolitan area network (MAN), or the Internet, for example.

The various methods and processes described herein may be implemented in a computer-readable medium using, for example, computer software, hardware, or some combination thereof. For a hardware implementation, the embodiments described herein may be performed by processor 506, which may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a selective combination thereof. For a software implementation, the embodiments described herein maybe implemented with separate software modules, such as procedures, functions, and the like, each of which perform one or more of the functions and operations described herein. The software codes can be implemented with a software application written in any suitable programming language and may be stored in a memory unit (for example, memory 508), and executed by a processor (for example, processor 506). The memory unit may be implemented within the processor or external to the processor, in which case it can be communicatively coupled to the processor using known communication techniques. The memory unit shown in FIG. 30 may be implemented using any type (or combination) of suitable volatile and nonvolatile memory or storage devices including random access memory (RAM), static random access memory (SRAM), electrically erasable programmable read-only memory (EEPROM), erasable programmable read-only memory (EPROM), programmable read-only memory (PROM), read-only memory (ROM), magnetic memory, flash memory, magnetic or optical disk, or other similar or effective memory or data storage device.

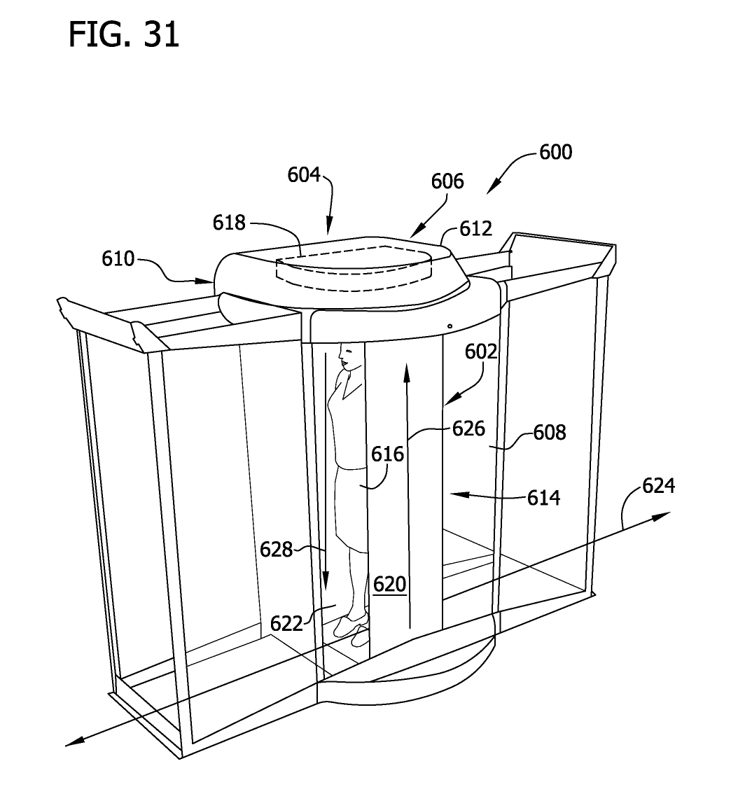

FIG. 31 is a perspective view of a QR inspection system 600, which includes an inductive sensor, such as a quadrupole resonance (QR) sensor 602. In alternative embodiments, the inductive sensor may be any suitable inductive sensor, such as a nuclear magnetic resonance (NMR) sensor or a metal detection sensor. QR inspection system 600 is adapted to operate in conjunction with a portal detection system. In a particular embodiment, QR inspection system 600 includes one or more nozzle interfaces (not shown) which are individually formed within the walls of QR inspection system 600. Each interface includes one or more nozzle apertures, which are sized to receive a linear jet array (not shown). Typically, the nozzle interfaces are welded, bolted, or otherwise attached or formed within their respective walls and may be constructed using the same conductive materials as the walls.

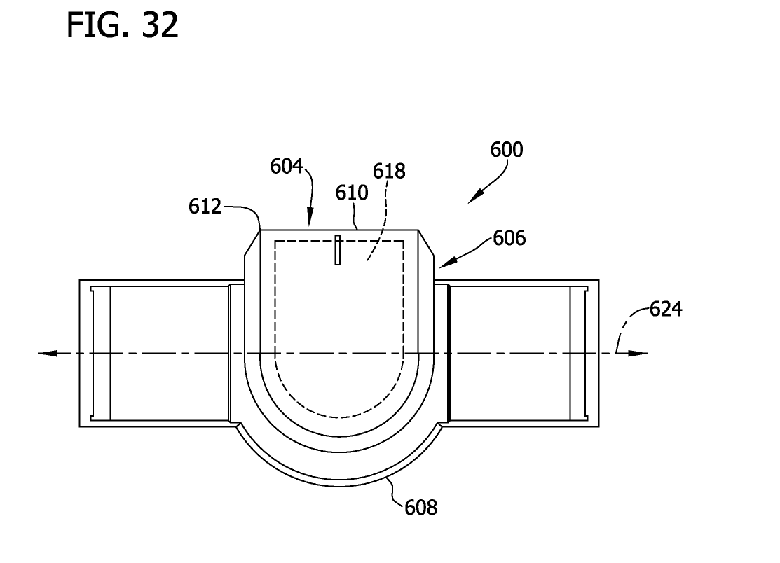

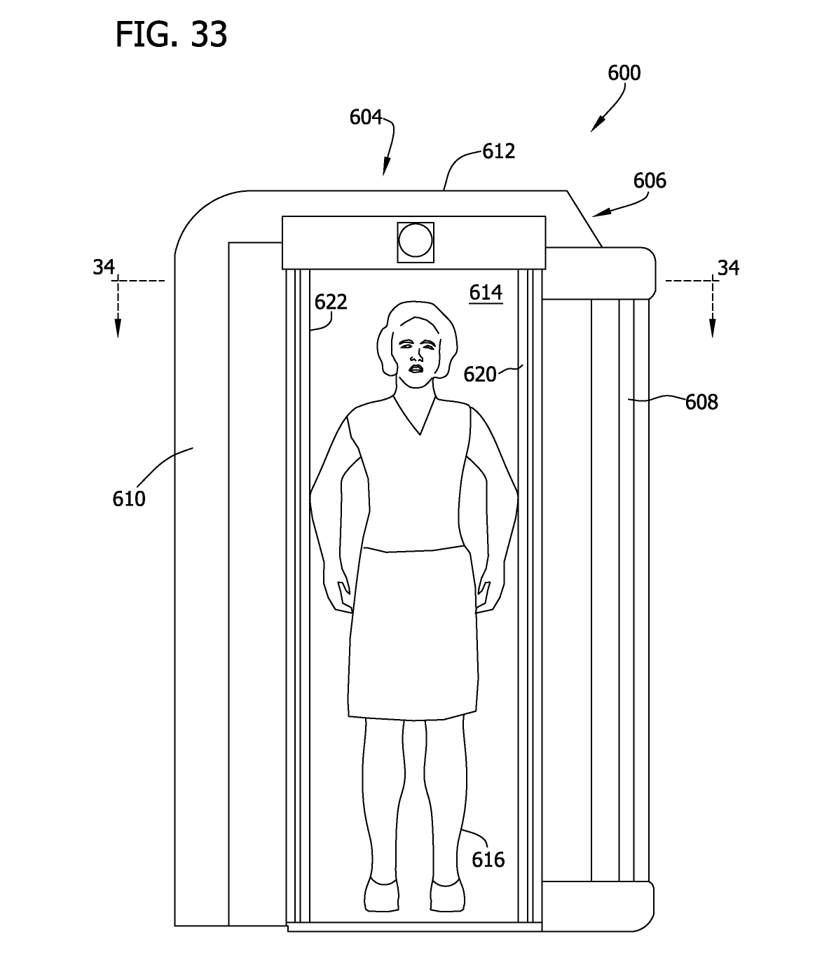

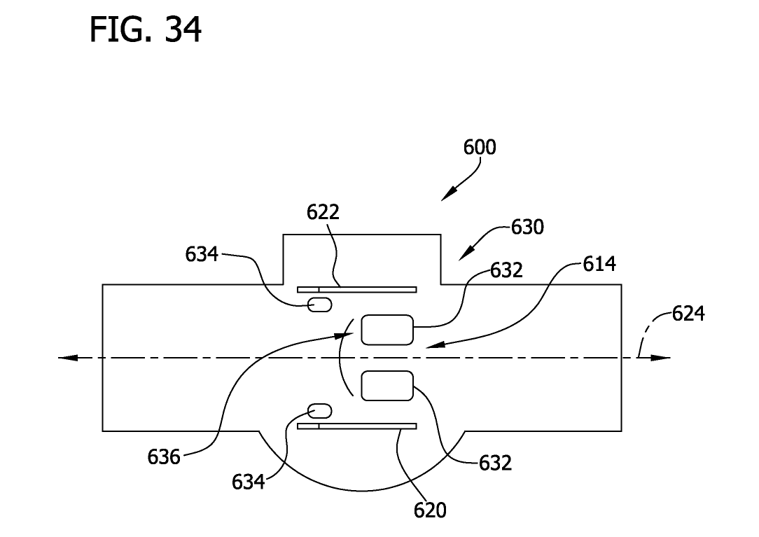

FIGS. 32 and 33 are top and end views, respectively, of QR inspection system 600. FIG. 34 is a cross-sectional view of QR inspection system 600 taken along line 34-34 of FIG. 33. QR inspection system 600 includes a walkthrough QR inspection system configured in association with a portal detection system 604. Portal detection system 604 includes a portal 606 having a first sidewall 608 and an opposing second sidewall 610. A ceiling or hood 612, made of a suitable material such as a plastic material, is coupled to and between first sidewall 608 and second sidewall 610. A passage 614 extends between first sidewall 608 and second sidewall 610 and beneath ceiling 612. Ceiling 612 may include an inlet with a fan for producing air flow that substantially matches the air flow rate provided by the human thermal plume. During operation, particles of interest will be entrained in the human thermal plume that exists in the boundary layer of air adjacent the inspected person 616, and will flow upwardly from person 616 to the detection apparatus in ceiling 612 of portal 606. In one embodiment, a trace detection system 618 is coupled to or with respect to ceiling 612 and is configured to detect minute particles of interest, such as traces of narcotics, explosives, and other contraband. Trace detection system 618 may be implemented using, for example, an ion trap mobility spectrometer. In some embodiments, portal detection system 604 may further include a plurality of air jets (not shown). The air jets are arranged to define a plurality of linear jet arrays with the air jets in each jet array being vertically aligned. Each air jet may be configured to direct a short puff of air inwardly and upwardly into passage 614 of portal 606.

Referring further to FIG. 32, in the exemplary embodiment QR sensor 602 includes two anti-symmetric current branches, namely first current branch 620 and opposing second current branch 622. First current branch 620 and second current branch 622 are positioned within passage 614 and located on opposing sides of a medial plane 624 of QR inspection system 600. As shown in FIG. 31, first current branch 620 is positioned on a first side of medial plane 624, while second current branch 622 is positioned on the opposite second side of medial plane 624. In this embodiment, first current branch 620 and second current branch 622 are substantially parallel and oriented in a vertical direction with respect to the ground or support surface of QR inspection system 600. During operation, current flows through first current branch 620 in a first direction represented by arrow 626 in FIG. 31, while current flows through second current branch 622 in a substantially opposite second direction represented by arrow 628, referred to herein as “antisymmetric current flow.” In general, QR sensor 602 includes, or is in communication with, an RF subsystem which provides electrical excitation signals to current branches 620 and 622. Using suitable techniques, the RF subsystem may utilize a variable frequency RF source to provide RF excitation signals at a frequency generally corresponding to a predefined, characteristic NQR frequency of a target substance. During the inspection process, the RF excitation signals generated by the RF source may be introduced to person 616. In some embodiments, QR sensor 602 may serve as a pickup coil for NQR signals generated by person 616, thus providing an NQR output signal which may be sampled to determine the presence of a target substance, such as an explosive.

Referring further to FIG. 34, in the exemplary embodiment QR inspection system 600 includes a safety device 630 to prevent or limit formation of a conducting loop by person 616, which may produce undesirable heat at a contact point or area. For example, if a person positioned within a conventional QR inspection system touches his or her eye to form a conducting loop from the shoulder through the arm to a contact point on the person's eye, excessive heat may be generated at the contact point, which may cause injury to the person's eye. To prevent or limit undesirable heat generation, safety device 630 includes one or more of the following: foot pads 632 and hand grips 634 positioned within magnetic field 636. Foot pads 632 and hand grips 634 are made of a suitable non-conductive material. With person 616 properly positioned within passage 614, each foot is positioned on a respective foot pad 632 and each hand is gripping a respective hand grip 634.

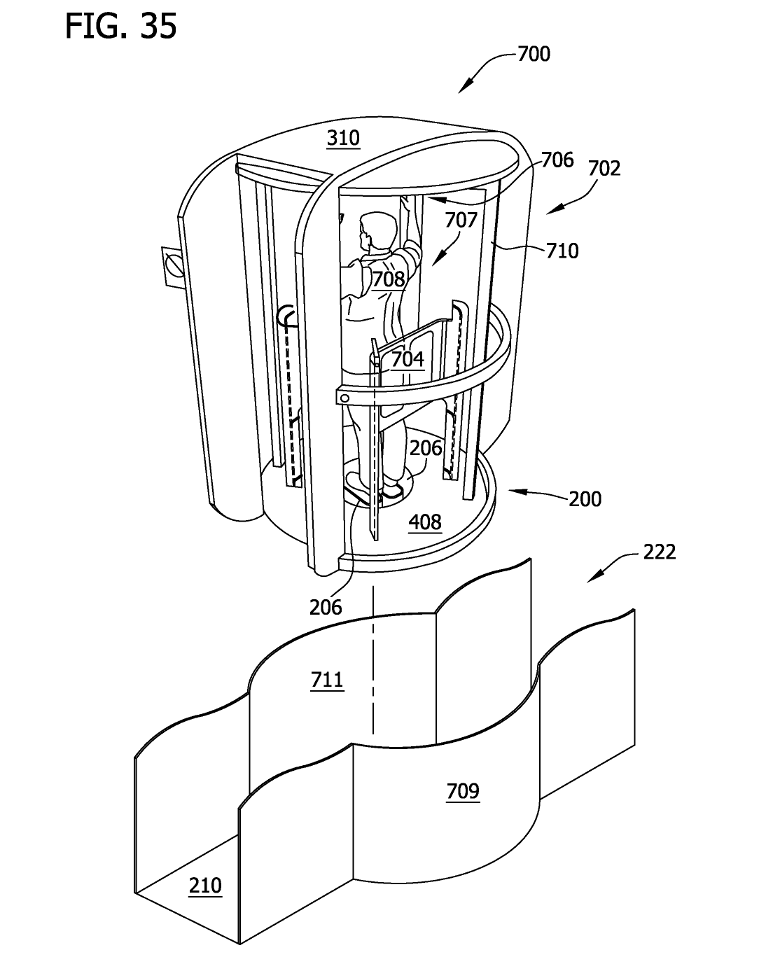

Furthermore, in some embodiments, scanner system 200 is incorporated as part of a passenger screening system 700. FIG. 35 is an exploded perspective view of an embodiment of shoe scanner system 200 incorporated as part of passenger screening system 700. Passenger screening system 700 also may include one or more of a MMW whole body imaging system 702, an additional inductive sensor system 704, a trace detection system 706, a wand detector system (not shown), or other passenger screening device. During a typical inspection process, a passenger 708 enters at entrance 222, and then stands within an inspection region 707. The inspection region 707 is positioned between a back wall 709 and a front wall 711. In some embodiments, the back wall 709 and/or front wall 711 extend between a floor and a ceiling, allowing the back wall 709, front wall 711, entrance ramp 208, exit ramp 210, floor 408, ceiling 310 and sensor housings 216 (not visible in FIG. 35) to be electrically connected to provide a more comprehensive RF shielding. In some embodiments, the back wall 709 and/or front wall 711 may be at least partially composed of semi-transparent material to reduce a perception by passenger 708 of confinement. In some embodiments, the back wall 709 and/or front wall 711 includes an aluminum honeycomb structure.

MMW whole body imaging system 702 includes a swing arm 710 that moves in a space between the back wall 709 and passenger 708 and between the front wall 711 and passenger 708. MMW whole body imaging system 702 is configured to provide a picture of articles that might be hidden under clothing of passenger 708. One or more inductive sensors 206 are located within inspection region proximate floor 408. In some embodiments, one or more inductive sensors 206 are thus located such that a sensitivity of scanner system 200 to a target contraband substance associated with shoes of passenger 708 is increased, while an interference of MMW whole body imaging system 702 with one or more inductive sensors 206 is limited. In addition, in some embodiments, one or more inductive sensors 206 are located such that they produce substantially no “shadow,” or obscured area, in a whole body image produced by MMW whole body imaging system 702.

In some embodiments, passenger screening system 700 includes a separate inductive sensor system 704. Inductive sensor system 704 may be, for example and without limitation, a metal detection system. Alternatively or additionally, inductive sensor system may be an NQR sensor system targeted at regions of passenger 708 other than shoes or other footwear, for example and without limitation, an abdominal region of passenger 708. The RF shielding provided by the back wall 709 and front wall 711 advantageously provides shielding for inductive sensor system 704 as well. In further embodiments, passenger screening system 700 includes a separate trace detection system 706. In some embodiments, and as shown in FIG. 35, trace detection system 706 is located within ceiling 310. In other embodiments, trace detection system 706 is located at another location within passenger inspection region 707. The back wall 709 and front wall 711 may advantageously create a barrier to an airflow into and out of passenger inspection region 707 to facilitate a detection of trace particles associated with passenger 708.

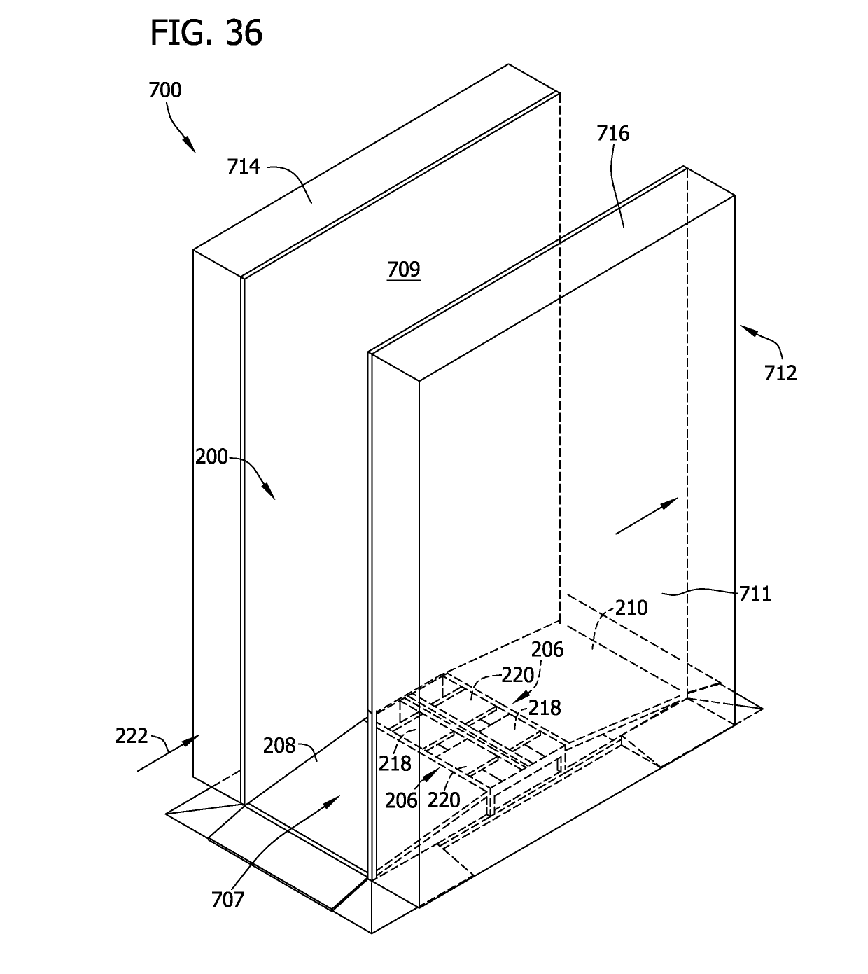

While passenger screening system 700 is shown in FIG. 35 as including a MMW whole body imaging system 702, it may alternatively include an XRB whole body imaging system 712, as shown in FIG. 36. FIG. 36 is a perspective view of scanner system 200 incorporated as part of a passenger screening system 700, including an XRB whole body imaging system 712. For simplicity, inductive sensor system 704 and trace detection system 706 are not shown in FIG. 36, but in certain embodiments one or both may be included as described above. In some embodiments, and as shown in FIG. 36, inspection region 707 lies between back wall 709 and front wall 711. XRB whole body imaging system 712 includes components 714 and 716. One or both of components 714 and 716 are configured to generate an X-ray scanning beam directed at a passenger (not shown) located in inspection region, and to collect a resulting pattern of deflected X-rays at one or more detectors (not shown) included in one or both of components 714 and 716.

As shown in FIG. 36, in some embodiments back wall and/or front wall extend between a floor (not shown) and a ceiling (not shown), allowing back wall 709, front wall 711, entrance ramp 208, exit ramp 210, the floor, ceiling and sensor housings 216 (not visible in FIG. 36) to be electrically connected to provide a more comprehensive RF shielding. Moreover, in some embodiments, back wall 709 is sufficiently thin to be located between the inspection region 707 and XRB whole body imaging system component 714, and/or front wall 711 is sufficiently thin to be located between the inspection region 707 and XRB whole body imaging system component 716, without degrading a quality of an image produced by XRB whole body imaging system 712. For example, in some embodiments back wall 709 and/or front wall 711 are equivalent to a thick sheet of aluminum foil. Moreover, in some embodiments, one or more inductive sensors 206 are located proximate the floor (not numbered) within the inspection region 707 such that a sensitivity of scanner system 200 to a target contraband substance associated with shoes of passenger 708 (not shown) is increased, while an interference of XRB whole body imaging system 712 with one or more inductive sensors 206 is limited. In addition, in some embodiments, one or more inductive sensors 206 are located such that they produce substantially no “shadow,” or obscured area, in a whole body image produced by XRB whole body imaging system 712. Thus, scanner system 200 may be integrated with XRB whole body imaging system 712 to reduce a footprint of passenger screening area. Further, in some embodiments, scanner system 200 operates simultaneously with XRB whole body imaging system 712. Thus, scanner system 200 may be integrated with XRB whole body imaging system 712 to reduce a time required to screen passenger 708 (not shown) for contraband. In alternative embodiments, scanner system 200 operates in sequence with XRB whole body imaging system 712.

Other embodiments of the invention include a wand, such as a QR wand, and RFI shielding to reduce or eliminate RFI of the wand. In an embodiment, the RFI shielding is a room that doubles as a passenger handling structure, such as a passenger waiting area, a passenger control room, a privacy booth, and/or a wanding station. Although a “wanding station” is referred to herein, the wanding station may be any suitable passenger handling structure. The wand described herein can be used in conjunction with imaging-based security apparatus. Imaging-based security systems include a millimeter wave system, an X-ray backscatter system, and/or any other suitable security system. Such imaging-based security apparatus, when used for security screening, provide images of articles that may be hidden under a passenger's clothes. When such a hidden article is identified under the clothes, an analysis is performed to determine the nature of the hidden article. In one embodiment, the analysis includes using a sensor, such as a chemical sensor, to determine if the hidden article is an explosive that has been concealed on the passenger. In the exemplary embodiment, location information regarding the hidden article is conveyed from the imaging system to a wanding station for automatic and/or operator directed positioning of a sensor, such as the wand, over the hidden article. Further, some embodiments described herein mitigate RFI by operating the wand in a shielded enclosure that can also function as a wanding station. More specifically, the wanding stations described herein prevent the passenger from exiting an inspection checkpoint until any anomalies and/or alarms have been resolved. Additionally, the wand is used in conjunction with an imaging system to identify anomalies. When used in conjunction with the imaging system, the wand does not need to perform sweeping scans. Rather, the wand is used in a stationary spot scan in which the anomalous article is targeted for analysis.

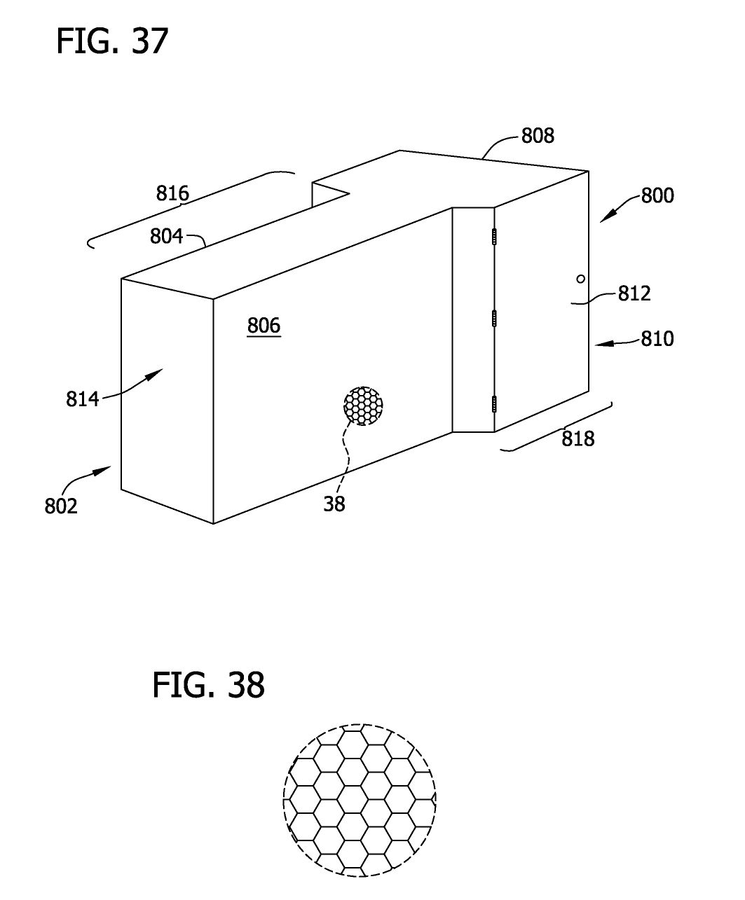

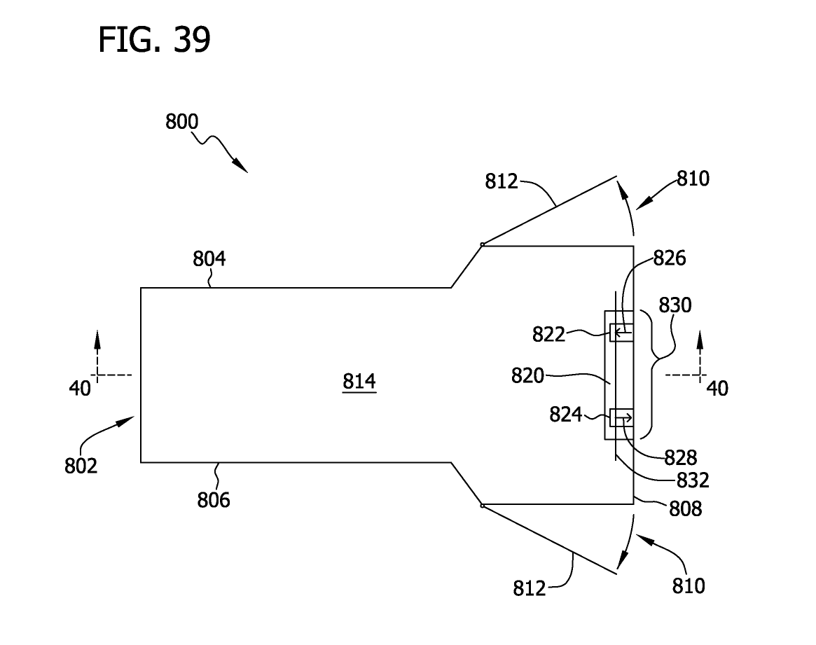

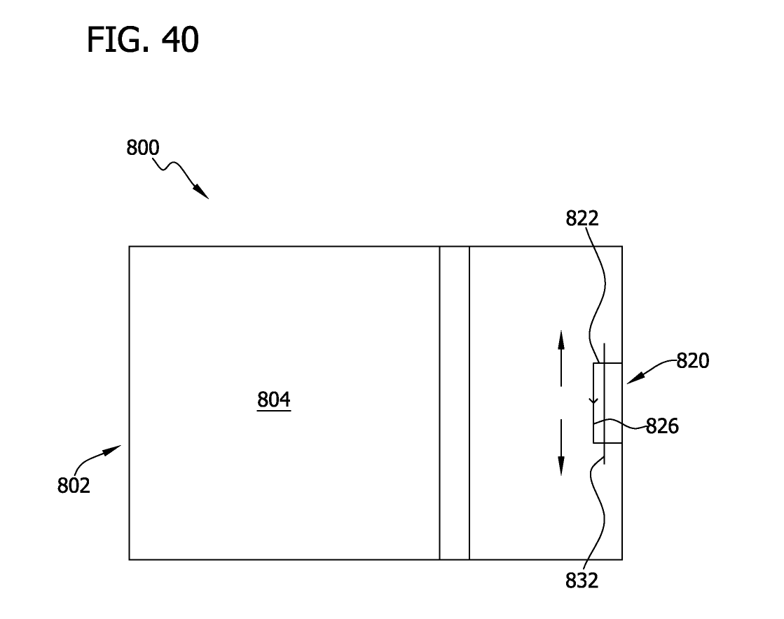

FIG. 37 is a perspective view of wanding station 800 that may be used to scan a passenger. FIG. 38 is an enlarged partial view of wanding station 800 taken at area 38 of FIG. 37. FIG. 39 is a top plan view of wanding station 800. FIG. 40 is a side view of wanding station 800 taken at line 40-40. In some embodiments, wanding station 800 includes an entrance 802, a first side wall 804, a second side wall 806, an end wall 808, and an exit 810. Additionally, in a particular embodiment, wanding station 800 includes a top wall. In the exemplary embodiment, exit 810 includes a door 812 defined in first side wall 804, second side wall 806, and/or end wall 808. For example, wanding station 800 includes a first door 812 defined in first side wall 804 and a second door 812 defined in second side wall 806. Entrance 802 may be open or include an entrance door for completely enclosing an interior space 814 of wanding station 800. In the exemplary embodiment, first side wall 804 and second side wall 806 are configured to define a narrow walkway 816 and a wider inspection area 818; however, first side wall 804 and/or second side wall 806 may have any suitable configuration.

In the exemplary embodiment, first side wall 804, second side wall 806, end wall 808, and doors 812 are formed from a material that shields a wand 820 within wanding station from RFI. For example, first side wall 804, second side wall 806, end wall 808, and doors 812 can be formed from aluminum, honey-combed aluminum, honey-comb LEXAN™, copper mesh, stacked cylinders of shield material, sheet of shielding material, and/or any other suitable shielding material. A honey-combed shielding material is shown in FIG. 38. In particular embodiments, the shielding material is at least partially transparent, however, the shielding material can be opaque to provide privacy. When wanding station 800 includes the top wall and/or the entrance door, the top wall and/or the entrance door are also formed from the shielding material. As such, wanding station 800 provides passive shielding of wand 820 for RFI.

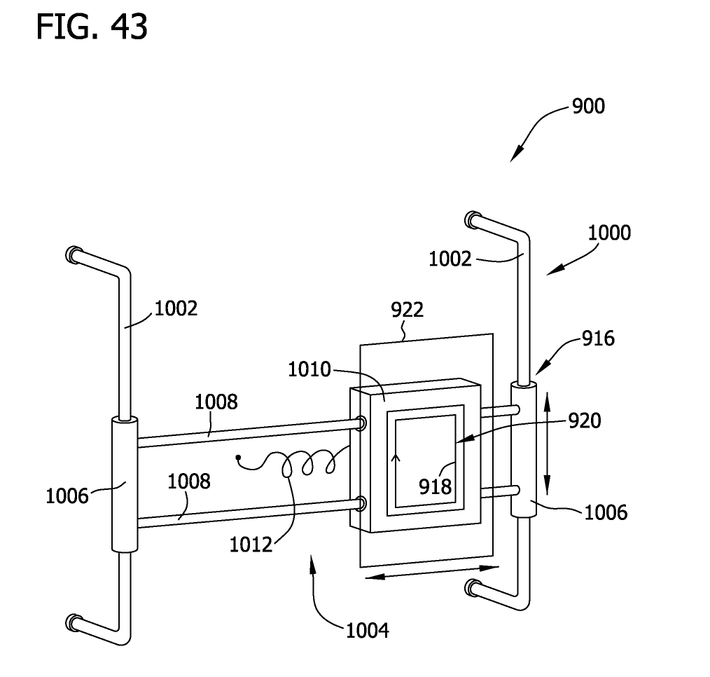

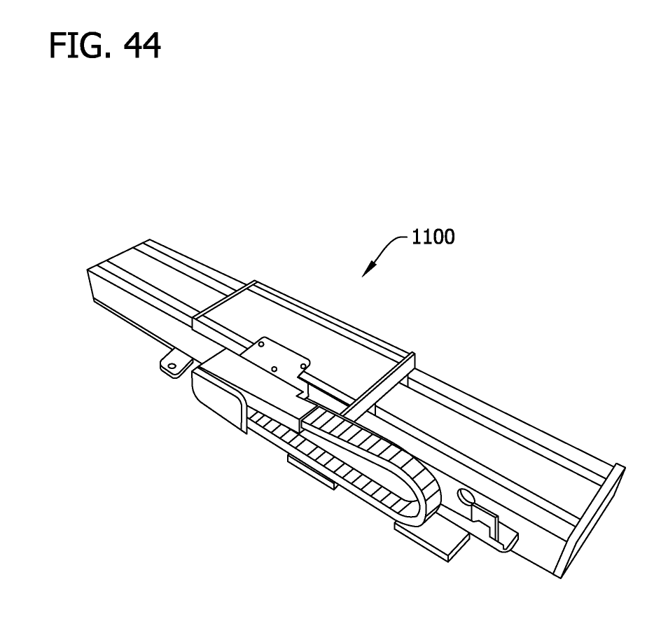

Wand 820 is coupled to first side wall 804, second side wall 806, and/or end wall 808. In the exemplary embodiment, wand 820 is coupled to end wall 808 and is moveable with respect to end wall 808. For example, wand 820 is configured to move vertically and/or horizontally with respect to end wall 808. Wand 820 may be coupled to end wall 808 using a mounting apparatus similar to the mounting apparatus shown in FIG. 43, a gantry similar to the gantry shown in FIG. 44, and/or any other suitable apparatus that enables wand 820 to function as described herein. In the exemplary embodiment, wand 820 is selectively positionable manually and/or automatically. In the exemplary embodiment, an image of the passenger acquired by an imaging system (not shown) is used by a control system (not shown) to automatically position wand 820 to analyze an anomalous and/or an alarmed object as determined from the image. Additionally, or alternatively, an operator at the control system can use the control system to remotely control a position of wand 820. In an alternative embodiment, an operator within wanding station 800 can manually position wand 820 with respect to the passenger.

Wand 820 is configured to detect metal, chemical compounds, and/or trace particles. More specifically, wand 820 includes a first current loop 822 and a second current loop 824. First current loop 822 has a first current 826 that flows in a first direction, and second current loop 824 has a second current 828 that flows in a second direction. In the exemplary embodiment, the first direction and the second direction are opposite to each other. First current loop 822 and second current loop 824 define a quadrupole resonance (QR) coil 830 within wand 820. Further, in the exemplary embodiment, end wall 808 includes image cutouts that enhance that shielding of end wall 808 to reduce a radiation resistance of QR coil 830. When wanding station 800 is not completely surrounded in the shielding material, a plane 832 of QR coil 830 is substantially parallel to end wall 808 while being movable to be positioned over an area of the passenger to be scanned. Alternatively, when wanding station 800 is substantially completely surrounded by the shielding material, for example, when wanding station 800 includes the top wall and the entrance door, plane 832 of QR coil 830 can be oriented arbitrarily with respect to first side wall 804, second side wall 806, and/or end wall 808. For example, wand 820 can be a hand-held wand. In the exemplary embodiment, wand 820 is operated at or near a normal human body temperature, i.e., approximately 37.0° C. In some embodiments, however, wand 820 is operated within a range of the normal human body temperature, such as plus or minus approximately six degrees Celsius. Accordingly, in the exemplary embodiment, wand 820 is operated at an operating frequency that is associated with the normal human body temperature. In some embodiments, however, wand 820 is operated within a range of operating frequencies that is associated with a range of temperatures that includes the normal human body temperature.

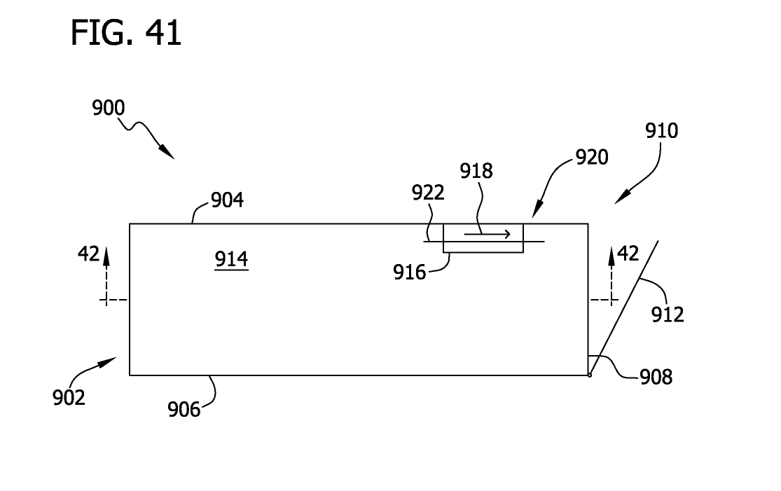

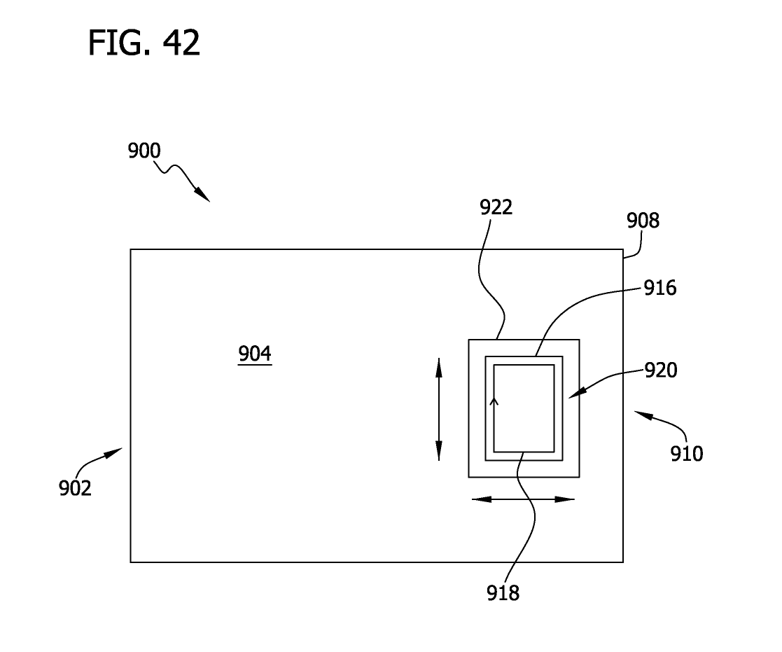

FIG. 41 is a top plan view of an alternative wanding station 900 that may be used to scan a passenger. FIG. 42 is a side view of wanding station 900 taken at line 42-42 of FIG. 41. FIG. 43 is a perspective view of a wand 916 that may be used with wanding station 900. Wanding station 900 includes an entrance 902, a first side wall 904, a second side wall 906, an end wall 908, and an exit 910. Additionally, in a particular embodiment, wanding station 900 includes a top wall. In the exemplary embodiment, exit 910 includes a door 912 defined in first side wall 904, second side wall 906, and/or end wall 908. For example, wanding station 900 includes one door 912 defined in end wall 908. Entrance 902 may be open or include an entrance door for completely enclosing an interior space 914 of wanding station 900. In the exemplary embodiment, first side wall 904 and second side wall 906 are substantially parallel to each other and each substantially located within one plane; however, first side wall 904 and/or second side wall 906 may have any suitable configuration.

Similar to the embodiment described above, first side wall 904, second side wall 906, end wall 908, and door 912 are formed from a material that shields a wand 916 within wanding station 900 from RFI. For example, first side wall 904, second side wall 906, end wall 908, and door 912 can be formed from aluminum, honeycombed aluminum, honey-comb LEXAN™, copper mesh, stacked cylinders of shield material, sheet of shielding material, and/or any other suitable shielding material. In particular embodiments, the shielding material is at least partially transparent, however, the shielding material can be opaque to provide privacy. When wanding station 900 includes the top wall and/or the entrance door, the top wall and/or the entrance door are also formed from the shielding material. As such, wanding station 900 provides passive shielding of wand 916 for RFI.

Wand 916 is coupled to first side wall 904, second side wall 906, and/or end wall 908. In the exemplary embodiment, wand 916 is coupled to first side wall 904 and is moveable with respect to first side wall 904. For example, wand 916 is configured to move vertically and/or horizontally with respect to first side wall 904. Wand 916 may be coupled to first side wall 904 using a mounting apparatus similar to the mounting apparatus shown in FIG. 43, a gantry similar to the gantry shown in FIG. 44, and/or any other suitable apparatus that enables wand 916 to function as described herein. In the exemplary embodiment, wand 916 is selectively positionable manually and/or automatically. In the exemplary embodiment, an image of the passenger acquired by an imaging system is used by a control system to automatically position wand 916 to analyze an anomalous and/or an alarmed object as determined from the image. Additionally, or alternatively, an operator at the control system can use the control system to remotely control a position of wand 916. In an alternative embodiment, an operator within wanding station 900 can manually position wand 916 with respect to the passenger.

Wand 916 is configured to detect metal, chemical compounds, and/or trace particles. More specifically, wand 916 includes a current loop 918 that flows in a first direction to define a quadrupole resonance (QR) coil 920 within wand 916. When wanding station 900 is not completely surrounded in the shielding material, a plane 922 of QR coil 920 is substantially parallel to first side wall 904 while being movable to be positioned over an area of the passenger to be scanned. Alternatively, when wanding station 900 is substantially completely surrounded by the shielding material, for example, when wanding station 900 includes the top wall and the entrance door, plane 922 of QR coil 920 can be oriented arbitrarily with respect to first side wall 904, second side wall 906, and/or end wall 908. For example, wand 916 can be a hand-held wand.

Referring to FIG. 43, mounting apparatus is configured to maintain plane 922 of QR coil 920 substantially parallel to first side wall 904, second side wall 906, and/or end wall 908 while allowing wand 916 to be selectively positioned with respect to a passenger. In the exemplary embodiment, mounting apparatus 1000 includes a pair of vertical bars 1002 coupled to first side wall 904, second side wall 906, and/or end wall 908. A sliding apparatus 1004 is coupled to vertical bars 1002 at cuffs 1006. A pair of horizontal bars 1008 is coupled to cuffs 1006 such that horizontal bars 1008 extend between vertical bars 1002. Cuffs 1006 include any suitable components that enable sliding apparatus 1004 to be automatically or manually positioned with respect to vertical bars 1002 and to be secured in position with respect to vertical bars 1002. Wand 916 is mounted in a block 1010 that is coupled to horizontal bars 1008. Block 1010 includes any suitable components that enable block 1010 to be automatically or manually positioned with respect to horizontal bars 1008 and to be secured in position with respect to horizontal bars 1008. Cuffs 1006, block 1010, horizontal bars 1008, and/or vertical bars 1002 can include TEFLON™ to facilitate reducing friction between components of mounting apparatus 1000.

A communication link 1012 is coupled in communication with wand 916 via block 1010 and with a control system. Communication link 1012 enables sliding apparatus 1004 and/or block 1010 to be positioned with respect to vertical bars 1002 and/or horizontal bars 1008 according to instructions from the control system. Further, communication link 1012 transmits signals from wand 916 to the control system for resolving an alarm and/or an anomaly, as described herein. In the exemplary embodiment, QR coil 920 can be relatively small to improve a filling factor and/or to reduce a likelihood of interaction of QR coil 920 and a medical device, such as a pacemaker.

FIG. 44 is a perspective view of a gantry 1100 that may be used with wanding station 800 (shown in FIGS. 37-39) and/or wanding station 900 (shown in FIGS. 41 and 42). In the exemplary embodiment, gantry 1100 can be coupled within wanding station 800 and/or wanding station 900 to enable wand 820 and/or wand 916 to be selectively positioned with respect to a passenger. In a particular embodiment, gantry 1100 is a servo controlled gantry mounted adjacent an exterior surface of first side wall 804 and/or 904, second side wall 806 and/or 906, and/or end wall 808 and/or 908.

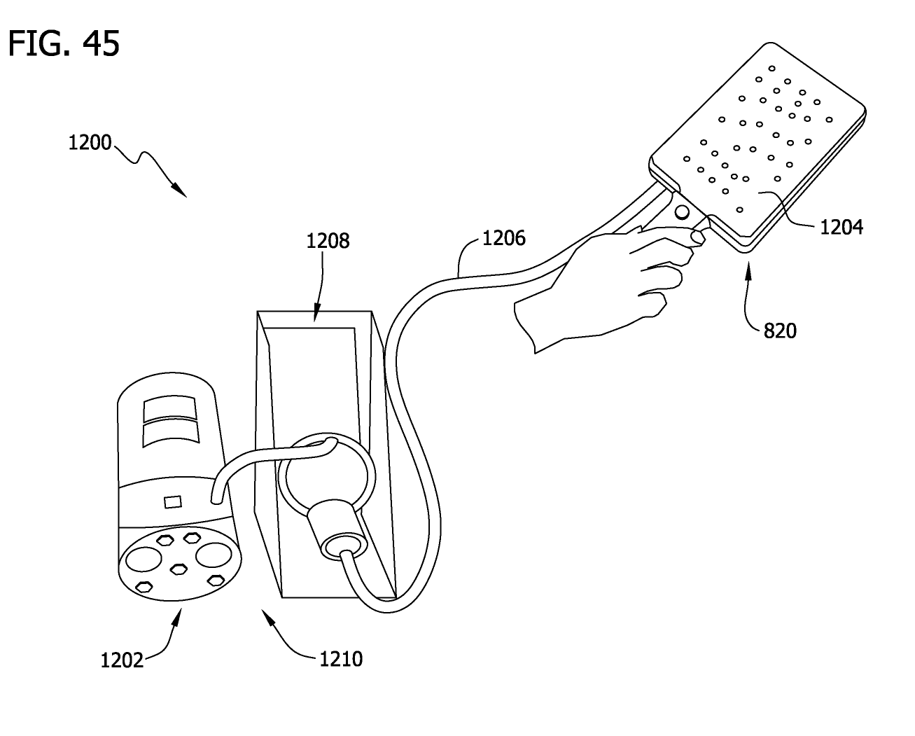

FIG. 45 is a schematic view of a trace detection system 1200 that may be used with wanding station 800 (shown in FIGS. 37-39) and/or wanding station 900 (shown in FIGS. 41 and 42). For the sake of simplicity, trace detection system 1200 will be described with respect to wanding station 800, however, it should be understood that trace detection system 1200 can also be used with wanding station 900. Trace detection system 1200 is configured to detect and/or identify trace particles and/or vapors associated with a passenger. More specifically, trace detection system 1200 includes an air system 1202 having one or more air intakes 1204 to collect trace particles and/or vapors from interior space 814 of wanding station 800. In the exemplary embodiment, air intakes 1204 are defined through a surface of wand 820, and an intake line 1206 is in flow communication with air intakes 1204 and a detector 1208.

Air from interior space 814 is captured by air intakes 1204 through the action of an intake motor 1210. In the exemplary embodiment, a control system controls the collection of air by communicating with an intake valve (not shown) and/or activates and deactivates intake motor 1210 directly to control air capture through air intakes 1204. Further, trace particles and/or vapors are identified in the air delivered through intake line 1206 by detector 1208, which uses any suitable trace particle and/or vapor detection technology. For example, but not by way of limitation, detector 1208 is an ion mobility spectrometer that analyzes trace particles and/or vapors in the air delivered through intake line 1206. Output of detector 1208 may be analyzed by the control system and/or by an operator of the control system to evaluate whether an alarmed object and/or an anomalous object is associated with a target material, such as an explosive material and/or a narcotic material.

Exemplary embodiments of systems and methods for detecting targeted substances are described above in detail. The systems and methods are not limited to the specific embodiments described herein but, rather, operations of the methods and/or components of the system and/or apparatus may be utilized independently and separately from other operations and/or components described herein. Further, the described operations and/or components may also be defined in, or used in combination with, other systems, methods, and/or apparatus, and are not limited to practice with only the systems, methods, and storage media as described herein.

A computer, such as those described herein, includes at least one processor or processing unit and a system memory. The computer typically has at least some form of computer readable media. By way of example and not limitation, computer readable media include computer storage media and communication media.

Computer storage media include volatile and nonvolatile, removable and non-removable media implemented in any method or technology for storage of information such as computer readable instructions, data structures, program modules, or other data. Communication media typically embody computer-readable instructions, data structures, program modules, or other data in a modulated data signal such as a carrier wave or other transport mechanism and include any information delivery media. Those skilled in the art are familiar with the modulated data signal, which has one or more of its characteristics set or changed in such a manner as to encode information in the signal. Combinations of any of the above are also included within the scope of computer readable media.

Although the present invention is described in connection with an exemplary explosive and/or narcotic detection system environment, embodiments of the invention are operational with numerous other general purpose or special purpose detection system environments or configurations. The detection system environment is not intended to suggest any limitation as to the scope of use or functionality of any aspect of the invention. Moreover, the detection system environment should not be interpreted as having any dependency or requirement relating to any one or combination of components illustrated in the exemplary operating environment. Examples of well known detection systems, environments, and/or configurations that may be suitable for use with aspects of the invention include, but are not limited to, personal computers, server computers, hand-held or laptop devices, multiprocessor systems, microprocessor-based systems, set top boxes, programmable consumer electronics, mobile telephones, network PCs, minicomputers, mainframe computers, distributed computing environments that include any of the above systems or devices, and the like.

Embodiments of the invention may be described in the general context of computer-executable instructions, such as program components or modules, executed by one or more computers or other devices. Aspects of the invention may be implemented with any number and organization of components or modules. For example, aspects of the invention are not limited to the specific computer-executable instructions or the specific components or modules illustrated in the figures and described herein. Alternative embodiments of the invention may include different computer-executable instructions or components having more or less functionality than illustrated and described herein.

The order of execution or performance of the operations in the embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

In some embodiments, the term “processor” refers generally to any programmable system including systems and microcontrollers, reduced instruction set circuits (RISC), application specific integrated circuits (ASIC), programmable logic circuits (PLC), and any other circuit or processor capable of executing the functions described herein. The above examples are exemplary only, and thus are not intended to limit in any way the definition and/or meaning of the term “processor.”

When introducing elements of aspects of the invention or embodiments thereof, the articles “a,” “an,” “the,” and “said” are intended to mean that there are one or more of the elements. The terms “comprising,” including,” and “having” are intended to be inclusive and mean that there may be additional elements other than the listed elements.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed:

1. A passenger scanning system comprising:
a passenger screening area configured for a person to enter;
a shield surrounding at least a portion of said passenger screening area, said shield configured to reduce a radio frequency interference within said passenger screening area; and
one or more sensors positioned in said passenger screening area at a height configured to be proximate one or more of an abdominal, groin and pelvic region of the entered person, said one or more sensors configured to generate a signal in response to a target substance located in said one or more of the abdominal, groin and pelvic region.

2. A passenger scanning system in accordance with claim 1, wherein said shield comprises a plurality of walls.

3. A passenger scanning system in accordance with claim 2, wherein said shield further comprises a platform coupled to said plurality of walls to define a chair configured to support the person.

4. A passenger scanning system in accordance with claim 1, wherein said one or more sensors comprises at least one quadrupole resonance (QR) sensor.

5. A passenger scanning system in accordance with claim 4, wherein said at least one QR sensor is configured to operate at a frequency related to a body temperature of the person.

6. A passenger scanning system in accordance with claim 1, wherein said one or more sensors comprises a plurality of current branches configured to conduct current anti-symmetrically.

7. A passenger scanning system in accordance with claim 6, wherein said plurality of current branches comprises a first current branch configured to conduct current in a first direction and a second current branch configured to conduct current in a second direction that is opposite the first direction, said first current branch and said second current branch positioned on opposite sides of a medial plane of said passenger scanning system.

8. A passenger scanning system comprising:
at least one wall and a platform coupled to said at least one wall to define a chair configured to support a person; and
a detection system comprising at least one inductive sensor configured to detect a change in a magnetic field of the person indicative of a presence of a target substance.

9. A passenger scanning system in accordance with claim 8, wherein said at least one wall comprises a first wall, a second wall, and a third wall, said first and second walls coupled to opposing end surfaces of said third wall.

10. A passenger scanning system in accordance with claim 8, wherein said chair defines a passenger screening area, said at least one wall and said platform coupled together to a shield surrounding at least a portion of said passenger screening area, said shield configured to reduce a radio frequency interference within said passenger screening area.

11. A passenger scanning system in accordance with claim 8, wherein said at least one inductive sensor comprises at least one quadrupole resonance (QR) sensor.

12. A passenger scanning system in accordance with claim 11, wherein said at least one QR sensor is configured to operate at a frequency related to a body temperature of the person.

13. A passenger scanning system in accordance with claim 8, wherein said at least one inductive sensor comprises a plurality of current branches configured to conduct current anti-symmetrically.

14. A passenger scanning system in accordance with claim 13, wherein said plurality of current branches comprises a first current branch configured to conduct current in a first direction and a second current branch configured to conduct current in a second direction that is opposite the first direction, said first current branch and said second current branch positioned on opposite sides of a medial plane of said passenger scanning system.

15. A passenger scanning system comprising:
a first sidewall;
a second sidewall positioned opposite said first sidewall;
a passage defined along a medial plane of said passenger scanning system and between said first and second sidewalls;
a first current branch positioned within said passage and on a first side of the medial plane;
a second current branch positioned within said passage and on a second side of the medial plane opposing the first side, the first current branch and the second current branch having anti-symmetric current flow; and
a safety device configured to limit undesirable heat generation within said passenger scanning system.

16. A passenger scanning system in accordance with claim 15, further comprising a shield surrounding at least a portion of said passage, said shield configured to reduce a radio frequency interference within said passage.

17. A passenger scanning system in accordance with claim 15, further comprising at least one sensor located within said passage, said at least one sensor positioned to be proximate a shoe of the entered passenger and configured to generate a signal in response to a target substance located in the shoe.

18. A passenger scanning system in accordance with claim 15, further comprising a floor coupled to said first and second side walls, wherein said first and second current branches are positioned within a sensor housing located in said floor.

19. A passenger scanning system in accordance with claim 18, wherein said first sidewall, said second sidewall, and said floor are coupled together to define a shield configured to reduce radio frequency interference within said passage.

20. A passenger scanning system in accordance with claim 15, further comprising an inductive sensor comprising said first and second current branches, said inductive sensor configured operate at a frequency related to a body temperature of a person.
